(19) United States
(12) Patent Application Publication
(10) Pub. No.: US 2010/0327285 A1
(43) Pub. Date: Dec. 30, 2010

(54) SEMICONDUCTOR DEVICE AND MANUFACTURING METHOD OF SEMICONDUCTOR DEVICE AND DISPLAY DEVICE AND MANUFACTURING METHOD OF DISPLAY DEVICE

(75) Inventors: Kazuto YAMAMOTO, Tokyo (JP); Katsuhiko Morosawa, Tokyo (JP)

Correspondence Address: HOLTZ, HOLTZ, GOODMAN & CHICK PC, 220 Fifth Avenue, 16TH Floor, NEW YORK, NY, 10001-7708, US

(73) Assignee: Casio Computer Co., Ltd., Tokyo (JP)

(21) Appl. No.: 12/820,362

(22) Filed: Jun. 22, 2010

(30) Foreign Application Priority Data
Jun. 26, 2009 (JP) 2009-153016
Jun. 30, 2009 (JP) 2009-155216

(51) Int. Cl. H01L 33/16; H01L 21/28; H01L 29/786; H01L 21/26

(52) U.S. Cl. 257/59; 438/585; 257/57; 438/34; 257/72; 257/E21.19; 257/E29.292; 257/E21.328; 257/E33.003; 257/E33.004

(57) ABSTRACT

Disclosed is a method of manufacturing a semiconductor device including: forming a photothermal conversion layer in a second area where a semiconductor layer is formed other than a first area where line is formed; and heating the semiconductor layer with the photothermal conversion layer by irradiating light on the first area and the second area.

### BACKGROUND OF THE INVENTION

1. Field of the Invention

The present invention relates to a semiconductor device and a manufacturing method of the semiconductor device and a display device and manufacturing method of the display device. In particular, the present invention relates to the semiconductor device including a transistor on a substrate, in which the transistor uses a crystalline or microcrystalline semiconductor layer and the manufacturing method of the semiconductor device. Also, the present invention relates to a display device on which the semiconductor device is applied and the manufacturing method of the display device.

2. Description of the Related Art

In recent years, a thin screen display such as a liquid crystal display device, organic electroluminescence display, plasma display, etc. are used as a display or monitor of a portable device such as a cellular telephone or digital camera, electronic devices such as a television, personal computer, etc. In display panels and driving drivers of such thin screen displays, generally, a transistor element using a silicon thin film as a channel layer is used.

It is well-known that a transistor element can be classified into two types which are an amorphous silicon transistor and a crystalline silicon transistor based on a solid state structure of the silicon thin film. The amorphous silicon transistor includes features such as an amorphous silicon thin film can be formed evenly in a large area at a low cost, and also the variation of the performance between neighboring elements is small. However, the electron mobility is low and for example, when the amorphous silicon transistor is applied to the display device and a circuit such as a driver is formed together with the pixel of the display area, there is a problem that sufficient performance as a driver circuit cannot be realized. Also, when the amorphous silicon transistor is driven for a long time, there is a defect that the threshold voltage (Vth) shifts.

On the other hand, as for the crystalline silicon transistor, the electron mobility is high and the shift of the threshold voltage Vth over time is small, and even if the driver circuit is formed together with the pixel of the display device as described above, there is a feature that sufficient performance as a driver circuit can be realized. As a method for forming a silicon thin film used in such crystalline silicon transistor, for example, a method such as Plasma Enhanced Chemical Vapor Deposition (PECVD) is used and therefore there is a known method where after the amorphous silicon thin film is formed, the amorphous silicon is melted and cooled to crystallize by heat anneal such as an infrared lamp or laser.

Here, when an amorphous silicon is crystallized by laser, usually an excimer laser with high absorbing coefficient in amorphous silicon is used. However, from the point of view of mass production, there is a problem that the output is unstable and maintenance is troublesome. Therefore, use of a semiconductor laser with more stable output and easier maintenance is proposed.

However, there is a problem that amorphous silicon has low absorbing coefficient to light with a wavelength of an infrared light or visible light emitted from a semiconductor laser. Therefore, as a method to heat anneal the amorphous silicon film efficiently, a method is proposed where after the amorphous silicon thin film is formed, a photothermal conversion layer with high light absorbing coefficient to infrared light and visible light is formed on the thin film. With this, a laser beam is exposed on the photothermal conversion layer and the photothermal conversion layer is heated so that the amorphous silicon in the layer below is annealed by the heat and crystallization can be performed efficiently. A method of forming such crystalline silicon layer is described in, for example, Japanese Patent Application Laid-Open Publication No. 2007-005508.

According to the above method of forming a crystalline silicon thin film shown in the above described cited documents, a photothermal layer is formed on an entire surface of the substrate on which the transistor element is formed, and there is a possibility that a portion which does not need heating is heated when the laser beam is irradiated. Therefore, there is a problem that when an area other than the area which is to be the channel layer of the crystalline silicon transistor such as the line section is heated, the film on the line is peeled or a crack occurs. Especially in the line section, the degree of heating becomes large, and there is a problem that the peeling of the film between the layer such as the silicon insulating film, etc. becomes clear, and manufacturing yield decreases. In order to avoid such problems, the laser beam needs to be irradiated locally so as not to heat the line portion, and there is a problem that the throughput (or operation efficiency) decreases in the irradiation step of the laser beam.

### SUMMARY OF THE INVENTION

The present invention has been made in consideration of the above situation, and one of the main objects is to provide a semiconductor device and manufacturing method of the semiconductor device and display device and manufacturing method of the display device which can suppress decrease of yield and throughput even when amorphous silicon thin film is laser annealed to form a crystalline silicon thin film.

In order to achieve any one of the above advantages, according to an aspect of the present invention, there is provided a method of manufacturing a semiconductor device including:

forming a photothermal conversion layer in a second area where a semiconductor layer is formed other than a first area where line is formed; and

heating the semiconductor layer with the photothermal conversion layer by irradiating light on the first area and the second area.

According to another aspect of the present invention, there is provided a semiconductor device manufactured by a method of manufacturing a semiconductor device including:

forming a photothermal conversion layer in a second area where a semiconductor layer is formed other than a first area where line is formed; and

heating the semiconductor layer with the photothermal conversion layer by irradiating light on the first area and the second area.

According to another aspect of the present invention, there is provided a method of manufacturing a display device including a plurality of display pixels including a display element and a pixel driving circuit to drive the display element, the method including:

forming a photothermal conversion layer in a second area in which the semiconductor layer is formed other than a first area in which line is formed;

heating the semiconductor layer with the photothermal conversion layer by irradiating light on the first area and the second area; and

forming a first transistor of the pixel driving circuit in which the crystallized semiconductor layer is to be a channel layer, the crystallized semiconductor layer formed by irradiating the light to perform heating.

According to another aspect of the present invention, there is provided a method of manufacturing a display device including a pixel array in which a plurality of display pixels are arranged, a selective driver section to set the display pixel to a selective state, and a data driver section to supply display data to the display pixel, the method including:

forming a photothermal conversion layer above a semiconductor layer of a second area which is to be the data driver section other than above the semiconductor layer of a first area which is to be the pixel array; and

heating the semiconductor layer of the data driver section with the photothermal conversion layer by irradiating light on the first area and the second area.

According to another aspect of the present invention, there is provided a display device including:

a plurality of display pixels including:

a display element; and

a pixel driving circuit to drive the display element, wherein

the pixel driving circuit includes a transistor including:

a semiconductor layer including a crystallized semiconductor area and an amorphous semiconductor area positioned on each of both edges of the crystallized semiconductor area; and

a channel protecting layer wider than the crystallized area positioned on the semiconductor layer.

According to another aspect of the present invention, there is provided a display device including:

a plurality of display pixels including:

a display element; and

a pixel driving circuit to drive the display element, wherein

the pixel driving circuit includes a transistor including:

a semiconductor layer including a crystallized semiconductor area and an amorphous semiconductor area positioned on one edge of the crystallized semiconductor area; and

a channel protecting layer positioned on the semiconductor layer and overlapped with a portion of the crystallized semiconductor area and a portion of the amorphous semiconductor area.

### BRIEF DESCRIPTION OF THE DRAWINGS

The present invention and the above-described objects, features and advantages thereof will become more fully understood from the following detailed description with the accompanying drawings and wherein;

FIG. 1 is a schematic cross sectional view showing a semiconductor device of the first embodiment;

FIG. 2A is a process diagram showing a schematic cross sectional view of an example of a manufacturing method of the semiconductor device of the first embodiment;

FIG. 2B is a process diagram showing a schematic cross sectional view of an example of a manufacturing method of the semiconductor device of the first embodiment;

FIG. 2C is a process diagram showing a schematic cross sectional view of an example of a manufacturing method of the semiconductor device of the first embodiment;

FIG. 2D is a process diagram showing a schematic cross sectional view of an example of a manufacturing method of the semiconductor device of the first embodiment;

FIG. 2E is a process diagram showing a schematic cross sectional view of an example of a manufacturing method of the semiconductor device of the first embodiment;

FIG. 3A is a process diagram showing a schematic cross sectional view of an example of a manufacturing method of the semiconductor device of the first embodiment;

FIG. 3B is a process diagram showing a schematic cross sectional view of an example of a manufacturing method of the semiconductor device of the first embodiment;

FIG. 3C is a process diagram showing a schematic cross sectional view of an example of a manufacturing method of the semiconductor device of the first embodiment;

FIG. 3D is a process diagram showing a schematic cross sectional view of an example of a manufacturing method of the semiconductor device of the first embodiment;

FIG. 3E is a process diagram showing a schematic cross sectional view of an example of a manufacturing method of the semiconductor device of the first embodiment;

FIG. 4A is a process diagram showing a schematic view of an example of a manufacturing method of the semiconductor device of a comparative example;

FIG. 4B is a process diagram showing a schematic view of an example of a manufacturing method of the semiconductor device of the comparative example;

FIG. 5 is a Raman spectrometric figure showing an example of crystallinity degree of the silicon thin film used in the transistor;

FIG. 6 is a schematic configuration diagram showing an example of a display device on which the semiconductor device of the present embodiment is applied;

FIG. 7 is an equivalent circuit diagram showing an example of a circuit configuration of the display pixel in which the semiconductor device of the present embodiment is applied;

FIG. 8 is a cross sectional configuration diagram schematically showing the substrate configuration of the display pixel in which the second embodiment is applied;

FIG. 9A is a process diagram showing a schematic cross sectional view of an example of a manufacturing method of the semiconductor device of the second embodiment;

FIG. 9B is a process diagram showing a schematic cross sectional view of an example of a manufacturing method of the semiconductor device of the second embodiment;

FIG. 9C is a process diagram showing a schematic cross sectional view of an example of a manufacturing method of the semiconductor device of the second embodiment;

FIG. 10A is a process diagram showing a schematic cross sectional view of an example of a manufacturing method of the semiconductor device of the second embodiment;

FIG. 10B is a process diagram showing a schematic cross sectional view of an example of a manufacturing method of the semiconductor device of the second embodiment;

FIG. 10C is a process diagram showing a schematic cross sectional view of an example of a manufacturing method of the semiconductor device of the second embodiment;

FIG. 11A is a process diagram showing a schematic cross sectional view of an example of a manufacturing method of the semiconductor device of the second embodiment;

FIG. 11B is a process diagram showing a schematic cross sectional view of an example of a manufacturing method of the semiconductor device of the second embodiment;

FIG. 11C is a process diagram showing a schematic cross sectional view of an example of a manufacturing method of the semiconductor device of the second embodiment;

FIG. 12 is a schematic configuration diagram showing another example of a display device in which the semiconductor device of the present embodiment is applied;

FIG. 13 is a planar view showing a layout configuration of the pixel of the EL panel;

FIG. 14 is a planar view showing a schematic configuration of the EL panel;

FIG. 15 is a circuit diagram showing a circuit corresponding to a pixel of the EL panel;

FIG. 16 is a planar view showing a pixel of the EL panel;

FIG. 17 is a cross sectional view of a face viewed along line XVII-XVII shown in FIG. 16;

FIG. 18 is a cross sectional view of a face viewed along line XVIII-XVIII shown in FIG. 16;

FIG. 19 is an explanatory diagram showing a step to form a gate in the forming step of the transistor;

FIG. 20 is an explanatory diagram showing a step to form two layers in the forming step of the transistor;

FIG. 21 is an explanatory diagram showing a first step of the processing film forming step in the forming step of the transistor;

FIG. 22 is an explanatory diagram showing a second step of the processing film forming step in the forming step of the transistor;

FIG. 23 is an explanatory diagram showing a third step of the processing film forming step in the forming step of the transistor;

FIG. 24 is an explanatory diagram showing a silicon crystallizing step in the forming step of the transistor;

FIG. 25 is an explanatory diagram showing a silicon crystallizing step in the forming step of the transistor;

FIG. 26 is an explanatory diagram showing a step to form the protecting insulating film in the forming step of the transistor;

FIG. 27 is an explanatory diagram showing a step to form the protecting film in the forming step of the transistor;

FIG. 28 is an explanatory diagram showing a step to form the extrinsic semiconductor layer forming step in the forming step of the transistor;

FIG. 29 is an explanatory diagram showing a step to form the semiconductor layer in the forming step of the transistor;

FIG. 30 is an explanatory diagram showing a step to form the source and the drain in the forming step of the transistor; and

FIG. 31 is a circuit diagram showing a circuit of an EL panel including a pixel of three transistors.

### DETAILED DESCRIPTION OF THE PREFERRED EMBODIMENTS

### First Example

A preferred embodiment for carrying out the present invention will be described below with reference to the attached drawings. The embodiments described below include various technically preferable limitations for carrying out the present invention, however, the scope of the invention is not limited to the embodiments described below and the illustrated examples.

### (Semiconductor Device)

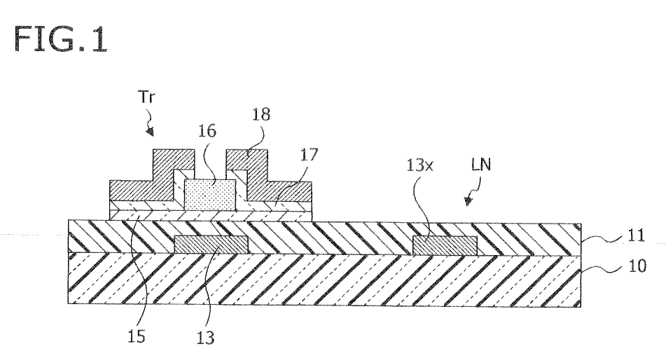

FIG. 1 is a schematic cross sectional view of the first embodiment of the semiconductor device. Here, to simplify description, FIG. 1 shows a configuration where one area of a transistor and one area of a line (wiring) layer are each provided.

As shown in FIG. 1, the semiconductor device of the present embodiment is provided with a transistor (crystalline silicon transistor) Tr including a semiconductor layer composed of polycrystalline silicon or microcrystalline silicon and the line layer LN including line 13x provided on a same layer on one face (top surface in the drawing) of an insulating substrate 10, such as glass, plastic, etc.

Specifically, as shown in FIG. 1, for example, the transistor Tr includes a gate electrode 13 provided on a surface of one face of an insulating substrate 10, a gate insulating film 11 formed between layers, a semiconductor layer (channel layer) 15 including crystalline silicon provided in an area corresponding to the gate electrode 13, a channel protecting layer 16 provided on the semiconductor layer 15, an extrinsic semiconductor layer (impurities layer) 17 provided extending on the semiconductor layer 15 from both edges of the channel protecting layer 16 and source electrode and drain electrode (hereinafter collectively referred to as “source and drain electrodes”) 18 provided aligned on the extrinsic semiconductor layer 17. As shown in FIG. 1, the line layer LN includes a line 13x provided on the same layer as the gate electrode 13 of the above described transistor Tr and is covered by the gate insulating film 11.

In FIG. 1, the source and drain electrodes 18 of the transistor Tr provided on the substrate 10 is shown in an exposed state, however in an actual product, an upper surface of the substrate 10 including the transistor Tr is covered and protected by an insulating film, etc. which is not shown. Also, a configuration can be formed on the configuration shown in FIG. 1 including a display element or line layer on the upper layer, etc. with an insulating film between layers and an evening film in between (for example, the later described organic EL element OEL, etc.).

As for the semiconductor device including the above described configuration, in the present embodiment, the transistor Tr includes a semiconductor layer 15 composed of crystalline silicon. As described later in the manufacturing method of the semiconductor device, here, in the present embodiment “crystalline” is defined as including a polycrystalline or microcrystalline film characteristic obtained by crystallizing an amorphous silicon thin film formed on the substrate 10 with thermal anneal. A more specific definition is described below.

### (Manufacturing Method)

Next, the manufacturing method of the above described semiconductor device is described with reference to the drawings.

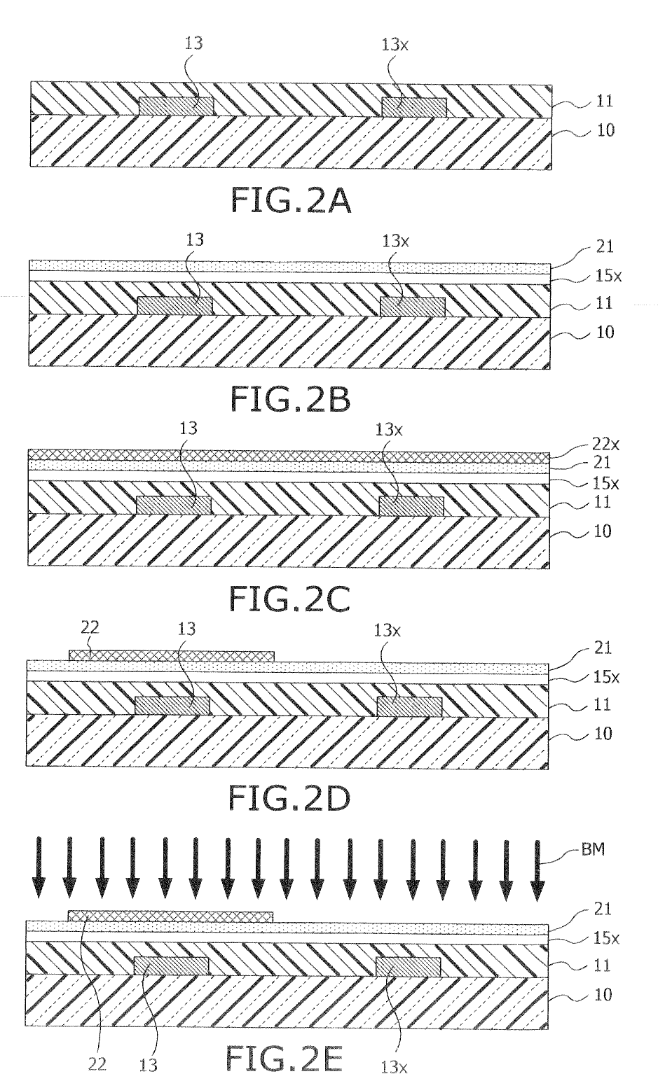

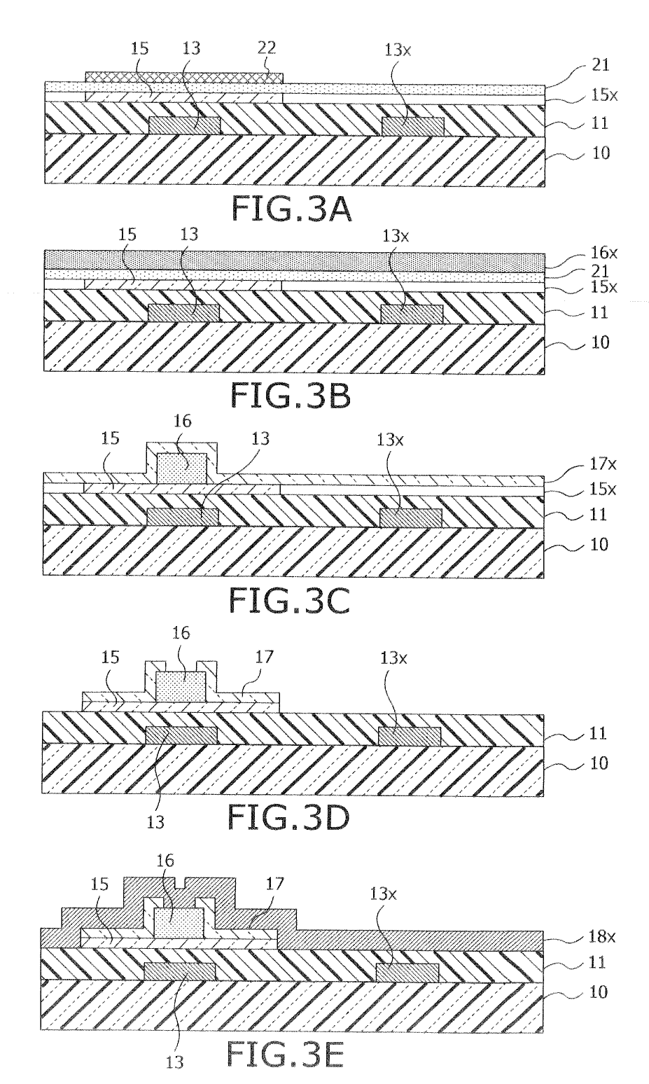

FIG. 2A to FIG. 3E are process diagrams showing a schematic cross sectional view describing an example of a manufacturing method of the semiconductor device of the present embodiment.

First, as shown in FIG. 2A, after forming a thin film including a conductive material on the insulating substrate 10 with a sputtering method, vapor deposition method, etc., a desired planar shape is patterned to form the gate electrode 13 of the transistor Tr and the line 13x. Here, as the material for the substrate 10, for example, alkali-free glass is used. Also, as gate metal for the gate electrode 13 and the line 13x, for example, single metal such as aluminum (Al), titanium (Ti), vanadium (V), chrome (Cr), manganese (Mn), iron (Fe), cobalt (Co), nickel (Ni), copper (Cu), zinc (Zn), zirconium (Zr), niobium (Nb), molybdenum (Mo), palladium (Pd), silver (Ag), indium (In), tin (Sn), tantalum (Ta), tungsten (W), platinum (Pt), gold (Au), etc., or compound including thereof, or metal material including an alloy thereof.

Next, the substrate 10 on which the gate electrode 13 and the line 13x are formed is set in the CVD device, and for example, by using a plasma CVD method, the gate insulating film 11 is formed on the entire substrate 10. With this, as shown in FIG. 2A, the gate electrode 13 and line 13x on the substrate 10 is covered by the gate insulating film 11. Here, as the gate insulating film 11, for example, a silicon nitride film or silicon oxide film is used.

Next, as shown in FIG. 2B, an amorphous silicon thin film 15x and a buffer layer 21 are successively formed on the entire substrate 10 using the plasma CVD method in the chamber of the above described CVD device. Specifically, as the film forming conditions of the amorphous silicon thin film 15x, gas flow rates of the silane gas and hydrogen gas are each set to silane gas/hydrogen gas=1500/190 (SCCM), power density is set to 0.034 W/cm², and pressure in the chamber is set to 50 Pa. Here, a suitable thickness of the amorphous silicon thin film 15x is about 5 to 100 nm. This is because when the thickness of the amorphous silicon thin film 15x is less than 5 nm, the amorphous silicon thin film 15x does not function as the thin film and when the amorphous silicon thin film 15x is too thick, resistance in the vertical direction increases on the substrate surface and also film stress increases and as a result cracks form easily.

As described later, when a metal thin film is used as a photothermal conversion layer 22x formed on the amorphous silicon thin film 15x, the buffer layer 21 is formed to be in between the amorphous silicon thin film 15x and the photothermal conversion layer 22x. As the buffer layer 21, for example, a silicon oxide film or silicon nitride film is used and the buffer layer 21 is formed to have a thickness of about 10 to 50 nm.

Next, the substrate 10 on which the amorphous silicon thin film 15x and buffer layer 21 are formed is taken out of the chamber and as shown in FIG. 2C, the photothermal conversion layer 22x is formed on the entire substrate 10. Here, when diamond like carbon (DLC) is used as the photothermal conversion layer 22x, the layer is formed by using a sputtering method with carbon as the target in a vacuum atmosphere on the substrate 10 set in the chamber of the sputtering device. Also, when a metal thin film is used as the photothermal conversion layer 22x, the layer is formed by using a sputtering method with a target of single metal such as molybdenum (Mo), chrome (Cr), aluminum (Al), titanium (Ti), niobium (Nb), etc., or an alloy thereof. The thickness of the photothermal conversion layer 22x is set to about 50 to 400 nm.

Also, when a metal thin layer is used as the photothermal conversion layer 22x, there is a possibility that the amorphous silicon and the metal chemically react to form silicide. Therefore, as described above, the buffer layer 21 including the insulating film is formed between the amorphous silicon thin film 15x and the photothermal conversion layer 22x including the metal thin layer.

Next, as shown in FIG. 2D, the above described photothermal conversion layer 22x is patterned using photolithography method and the photothermal conversion layer 22 including a predetermined planar shape is formed. Specifically, first a photoresist which is not shown is patterned so as to remain only on an area which is to be the channel layer of the transistor Tr (in other words, an area including the area where the above described gate electrode 13 is formed and an area desired to crystallize the amorphous silicon thin film 15x by laser anneal which is described later) and the photothermal conversion layer 22x of the lower layer is etched using the photoresist. When the above described diamond like carbon (DLC) is used as the photothermal conversion layer 22x, etching method by the dry etching method using oxygen plasma is performed. When the above described metal thin layer is used as the photothermal conversion layer 22x, etching method by wet etching method or dry etching method is performed using an etchant suitable for each thin film material.

Next, as shown in FIG. 2E, a laser beam BM is irradiated on the entire substrate 10 using a semiconductor laser device (not shown) and only the amorphous silicon thin film 15x of the lower layer of the photothermal conversion layer 22 is heat annealed (laser anneal). With this, only the amorphous silicon thin layer 15x directly under the area where the photothermal conversion layer 22 is remaining is crystallized and the semiconductor layer 15 including a polycrystalline silicon thin film or microcrystalline silicon thin film is formed.

Specifically, as the laser beam source used in the laser anneal, for example, a broad area type high output semiconductor laser device with a wavelength of 808 nm is used. In such semiconductor laser device, a laser beam with a light output of about 4 W is successively emitted and forms a desired beam shape through even illumination optics such as a micro lens array. Further, the beam is gathered to an optical intensity of about 2 mW/μm², and is irradiated while moving the substrate 10 at a certain speed for example, about 40 mm/s. In other words, by scanning with a laser beam BM with a predetermined irradiating range, the laser beam BM is irradiated on the entire substrate 10 and heat anneal is performed.

With this, the film material which forms the photothermal conversion layer 22 is heated to a high temperature and the heat is conducted by thermal conduction through the buffer layer 21 of the lower layer and to the amorphous silicon thin film 15x. Then, the amorphous silicon thin film 15x reaches the melting point and is heat annealed so that only the amorphous silicon thin film 15x directly below the photothermal conversion layer 22 is crystallized and the semiconductor layer 15 including the microcrystalline silicon thin film is formed as shown in FIG. 3A. With this, the amorphous silicon thin film 15x of the area which is to be the channel layer of the transistor Tr is crystallized according to the set conditions of the laser anneal so as to be able to form the semiconductor layer 15 including the polycrystalline silicon thin film or microcrystalline silicon thin film. As for the amorphous silicon thin film 15x of the area where the photothermal conversion layer 22 is not formed, since the absorption coefficient (light absorption index) is low, the laser beam BM passes through and the amorphous silicon thin film 15 is not heated. Therefore, the amorphous state is maintained.

Next, as shown in FIG. 3B, after the photothermal conversion layer 22 on the buffer layer 21 is removed, for example, a plasma CVD method is used to form the insulating layer 16x which is to be the channel protecting layer on the entire substrate 10. Here, the method as same as the above described step of forming a pattern of the photothermal conversion layer 22x (dry etching method or wet etching method according to film material) can be applied as the removing method of the photothermal conversion layer 22. Also, similar to the above described gate insulating film 11 or buffer layer 21, for example, a silicon nitride film or silicon oxide film is used as the insulating layer 16x.

Next, as shown in FIG. 3C, the above described insulating layer 16x and buffer layer 21 are successively patterned using photolithography method and the channel protecting layer 16 including a predetermined planar shape is formed. Specifically, a photoresist which is not shown is patterned so as to remain only on an area which is to be the channel layer of the transistor Tr and corresponding to the area where the above described gate electrode 13 is formed, and the insulating layer 16x and the buffer layer 21 of the lower layer are successively etched by dry etching method using the photoresist. With this, the channel protecting layer 16 which is a laminated body of the insulating layer 16x and the buffer layer 21 is formed.

Next, as shown in FIG. 3C, the extrinsic semiconductor layer (impurities layer) 17x to form the source and drain of the transistor Tr is formed on the entire substrate 10. Material used for the extrinsic semiconductor layer 17x is different depending on whether the transistor Tr to be formed is p-type or n-type. In a p-type transistor, a silicon layer (p⁺-Si layer) where an acceptor type impurity such as diborane, etc. is mixed with silane gas is formed using the plasma CVD method to form the extrinsic semiconductor layer 17x. In an n-type transistor, a silicon layer (n⁺-Si layer) where a donor type impurity such as arsine, phosphine, etc. is mixed with silane gas is formed using the plasma CVD method to form the extrinsic semiconductor layer 17x. Also, the thickness of the extrinsic semiconductor layer 17x is set to be about to 100 nm for the same reasons as the above described amorphous silicon thin film layer 15x which is a non-dope silicon layer (i-Si layer).

Next, as shown in FIG. 3D, the extrinsic semiconductor layer 17x is patterned to form the extrinsic semiconductor layer 17 including a planar shape extending on the semiconductor layer 15 from both edges of the channel protecting layer 16 and removes the amorphous silicon thin film 15x other than the semiconductor layer 15 of the area which is to be the channel layer of the transistor Tr. Specifically, a photoresist which is not shown is patterned so as to remain only on an area corresponding to the planar shape of the source and drain electrodes 18 of the transistor Tr, and the extrinsic semiconductor layer 17x and amorphous silicon thin layer 15x of the lower layer are successively etched by dry etching method using the photoresist. With this, the extrinsic semiconductor layer 17 is formed on the area where the transistor Tr is formed and the amorphous silicon thin film 15x of the area other than where the transistor Tr is formed is removed and the gate insulating film 11 is exposed.

Next, as shown in FIG. 3E, a drain metal layer 18x to form the source and drain electrodes 18 of the transistor Tr is formed on the entire substrate 10. The drain metal layer 18x is formed using for example, the sputtering method so as to include an electrode configuration with laminated electrode layers including single metal such as chrome (Cr), aluminum (Al), titanium (Ti), niobium (Nb), etc., or an alloy thereof.

Next, the drain metal layer 18x is patterned so as to include a predetermined planar shape and as shown in FIG. 1, the source and drain electrodes 18 are formed on the extrinsic semiconductor layer 17 of the transistor Tr. Specifically, a photoresist which is not shown is patterned so as to remain only on an area corresponding to the planar shape of the source and drain electrodes 18 of the transistor Tr, and the drain metal layer 18x of the lower layer is etched by dry etching method using the photoresist. With this, the extrinsic semiconductor layer 17 and the source and drain electrodes 18 including a planar shape extending on the semiconductor layer 15 from both edges of the channel protecting layer 16 are formed on the area where the transistor Tr is formed.

In the above described manufacturing method of the semiconductor device, an example is described where the removal of the amorphous silicon thin film 15x and the patterning of the extrinsic semiconductor layer 17 and the source and drain electrodes 18 are performed in different steps. The present invention is not limited to this example, and the following manufacturing method can be applied.

In other words, as described in FIG. 3C, after forming a pattern of the channel protecting layer 16 in the area which is to be the channel layer of the transistor Tr, the extrinsic semiconductor layer 17x and the drain metal layer 18x are successively formed on the substrate 10. Then, patterning is performed so that the photoresist remains only on the area corresponding to the planar shape of the source and drain electrodes 18 and the photoresist is used to first perform dry etching method on the drain metal layer 18x to form the source and drain electrodes 18. Next, the patterned source and drain electrodes 18 are used as a mask to successively perform dry etching method on the extrinsic semiconductor layer 17x and the amorphous silicon thin film 15x of the lower layer to form the extrinsic semiconductor layer 17 aligned with the source and drain electrodes 18 and to remove the amorphous silicon thin film 15x. With such manufacturing method, the number of steps of photolithography method and patterning can be decreased and thus enhance manufacturing efficiency.

Next, the advantageous effects of the semiconductor device and the manufacturing method of the present embodiment are described in detail with comparative examples.

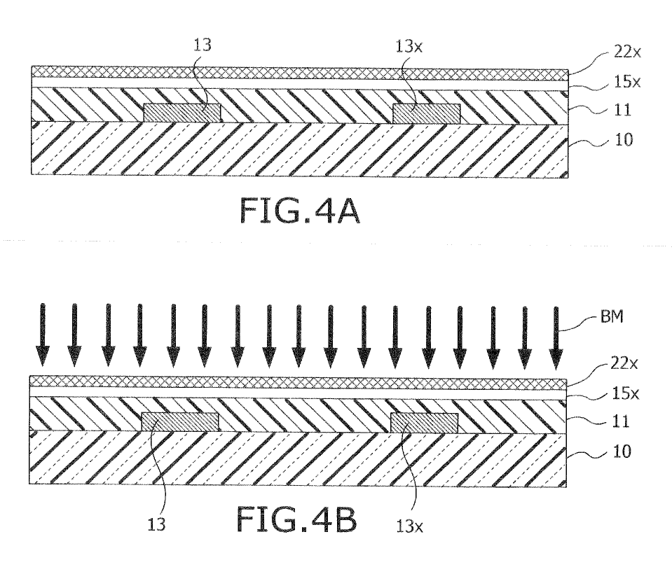

FIGS. 4A and 4B are each a schematic process diagram showing an example of a manufacturing method of a semiconductor device using a conventional technique (hereinafter referred to as “comparative example”) to describe the advantageous effects of the semiconductor device and the manufacturing method of the semiconductor device of the present embodiment. Here, configuration and manufacturing steps similar to the present embodiment are referred to with similar reference numerals and the description is simplified with reference to FIG. 2A to FIG. 3E or the description is omitted.

According to the manufacturing method of the semiconductor device of the comparative example, as shown in the above described first embodiment, after the gate electrode 13 and the line 13x are patterned on the substrate 10 as shown in FIG. 2A, the gate insulating film 11, the amorphous silicon thin film 15x and the photothermal conversion layer 22x are successively laminated and formed on the entire substrate 10 as shown in FIG. 4A. Then, as shown in FIG. 4B, the laser beam BM including a predetermined irradiation area emitted from the semiconductor laser device which is not shown is scanned and the entire substrate 10 is irradiated and heat annealed with the laser beam BM.

In such manufacturing method, the laser beam is irradiated in a state where the photothermal conversion layer 22x is formed on the entire substrate 10 and an area other than the forming area of the transistor Tr (channel layer) which needs to be heat annealed is heated due to the photothermal conversion layer 22x. In this case, for example, due to the difference of heat absorption coefficient and heat expansion coefficient between the line 13x and the silicon nitride film and the silicon oxide film composing the gate insulating film 11, there is a problem such as peeling and cracking occur in the gate insulating film 11 on the line 13x. As a method to avoid the above, it is conceived to scan the laser beam so that only the area where heat anneal is necessary (forming area of the transistor Tr) is irradiated and the area where heat anneal is not necessary (for example forming area of the line LN, etc.) is not irradiated. However, with such method there is a problem that the throughput (operation efficiency) of the irradiation step of the laser beam reduces.

Alternatively, the semiconductor device and the manufacturing method of the semiconductor device of the present embodiment include a method of forming the photothermal conversion layer 22 on only the area which is to be the channel layer of the transistor Tr and then irradiating with the laser beam BM to perform heat annealing when the amorphous silicon thin film 15x is crystallized. With this, only the amorphous silicon thin film 15x in the area where the transistor Tr (channel layer) is formed can be efficiently heated and crystallized. Further, the heating by the heat annealing in an area other than where the transistor Tr is formed, such as the area where the line 13x is formed, can be suppressed. Consequently, the peeling and the cracking of the gate insulating film 11, etc. can be prevented and the reduction of manufacturing yield can be suppressed. Also, in this case, similar to the above described comparative example, the laser beam BM is scanned to irradiate the entire substrate 10 and the reduction of throughput (operation efficiency) in the irradiating step of the laser beam BM does not occur.

Here, the element attribute of the transistor Tr applied to the semiconductor device of the present embodiment is described.

According to the above described semiconductor device and the manufacturing method of the semiconductor device, a transistor including a polycrystalline or microcrystalline silicon thin film as a semiconductor layer is described as the transistor Tr including the semiconductor layer including the crystalline silicon formed by laser annealing.

Especially, as for the transistor (microcrystalline silicon transistor) including the microcrystalline silicon thin film as the semiconductor layer, although the electron mobility is slightly lower compared to the polycrystalline silicon transistor, the electron mobility is larger compared to the amorphous silicon transistor. Further, the change of the threshold value voltage Vth is also small to a degree similar to the polycrystalline silicon transistor and the variation of performance between the close elements is small to a degree similar to the amorphous silicon transistor. Such advantageous features are included in the microcrystalline silicon transistor.

Such microcrystalline silicon is set to be with, generally, the particle diameter of the crystal in a range of an order of few tens nm to few μm and a state where amorphous silicon is included within the crystallized silicon thin film at about 30%. Here, the degree of crystallization is specifically analyzed by showing actually measured data of Raman spectroscopy of a specimen (crystalline silicon thin film) formed by heat annealing by irradiating a laser beam on amorphous silicon thin film based on the set condition of laser anneal shown in the above described manufacturing method of the semiconductor device.

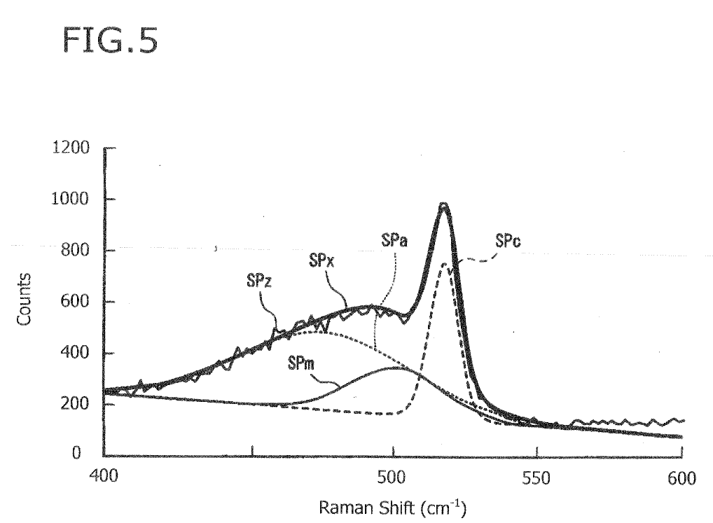

FIG. 5 is a Raman spectroscopic figure showing an example of degree of crystallization of the silicon thin film used in the transistor.

As shown in FIG. 5, the measured spectrum SPz of the sample measured by Raman spectroscopy substantially matches to the curve SPx of the calculated value of the total amount of a peak intensity of a typical spectrum SPc in a crystalline silicon (polycrystalline) (about 520 cm⁻¹), a peak intensity of a typical spectrum SPm in a microcrystalline silicon (about 500 cm⁻¹), and a peak intensity of a typical spectrum SPa of an amorphous silicon (about 470 cm⁻¹). In other words, the microcrystalline silicon thin film is a state where the amorphous, microcrystalline and crystalline silicon exist together and as shown in FIG. 5, the measured spectrum SPz can be resolved to three peaks of crystalline silicon, microcrystalline silicon, and amorphous silicon. With this, the degree of crystallization of the silicon can be represented by the following formula (I)

degree of crystallization=(Ic-Si+Iμc-Si)/(Ic-Si+Iμc-Si+Ia-Si) (1)

In the formula (I), Ic-Si is the peak intensity of the crystalline (polycrystalline) silicon of the Raman spectrum, Iμc-Si is the peak intensity of the microcrystalline silicon of the Raman spectrum, Ia-Si is the peak intensity of the amorphous silicon of the Raman spectrum. The degree of crystallization of the above specimen with the measured spectrum SPz shown in FIG. 5 calculated based on the formula (I) is 72.2%, and since the amount of amorphous silicon included is about 30%, it can be determined that the microcrystalline silicon is formed.

Next, the semiconductor device and the display device of the second embodiment of the present embodiment are described.

In the above described first embodiment, a case where a transistor Tr including a semiconductor layer including crystalline (polycrystalline or microcrystalline) silicon and a line layer LN are formed simultaneously on a single substrate 10 is described. In the second embodiment, a case where a crystalline silicon transistor, amorphous silicon transistor and line layer are formed simultaneously on a single substrate 10 is described.

### (Display Device)

First, the display device and display pixel where the semiconductor device and the manufacturing method of the semiconductor device of the present embodiment can be applied are described. The embodiment shown below describes a case where a display panel includes a configuration of aligning in two dimensions a plurality of display pixels including organic electroluminescence elements (organic EL elements) and applying the semiconductor device of the present embodiment in the organic EL display panel which displays image information by allowing each display element to perform light emitting operation at a luminance tone according to the display data (video data). Alternatively, the semiconductor device of the present invention can be applied to a display panel which displays image information by other display methods.

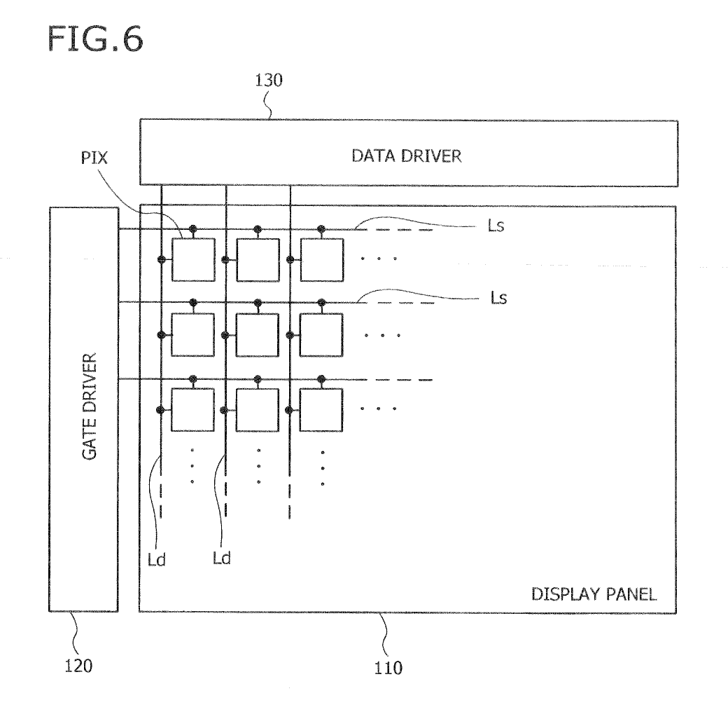

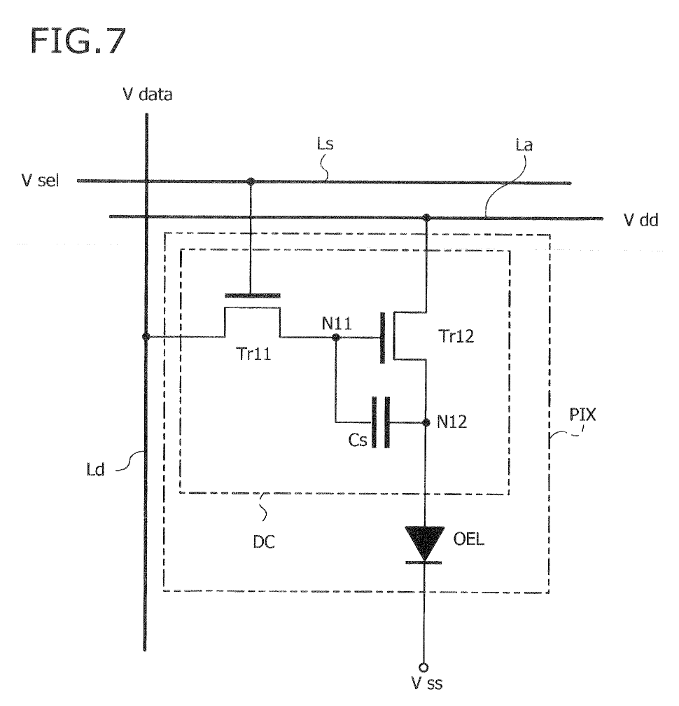

FIG. 6 is a schematic block diagram showing an example of a display device in which the semiconductor device of the present embodiment is applied. FIG. 7 is an equivalent circuit diagram showing an example of a configuration of a circuit of a display pixel in which the semiconductor device of the present embodiment is applied.

A display device in which the semiconductor device of the present embodiment can be applied includes, as shown in FIG. 6, at least a display panel 110 where a plurality of display pixels PIX are aligned in two dimensions, a gate driver 120 to set each display pixel PIX to a selective state, and a data driver 130 to feed a tone signal to each display pixel PIX according to display data.

### (Display Pixel)

As shown in FIG. 7, each display pixel PIX includes pixel driving circuit DC and organic EL element OEL. The pixel driving circuit DC provides light emitting driving current of a current value according to the display data to the organic EL element OEL and each display pixel PIX emits light at a predetermined luminance tone according to the display data.

For example as shown in FIG. 7, the pixel driving circuit DC includes a transistor Tr11, transistor Tr12, and capacitor Cs. As for the transistor Tr11, the gate terminal is connected to the selective line Ls, the drain terminal is connected to the data line Ld, and the source terminal is connected to the contact point N11, respectively. As for the transistor Tr12, the gate terminal is connected to the contact point N11, the drain terminal is connected to the power source voltage line La on which a predetermined high potential voltage Vdd is applied, and the source terminal is connected to the contact point N12, respectively. The capacitor Cs is connected between the gate terminal and source terminal (contact point N11 and contact point N12) of the transistor Tr12. At least one of the selective line Ls or the data line Ld is to be the line 13x.

Here, an n-channel type transistor (electrolysis effect type transistor) is applied to the transistors Tr11 and Tr12. When the transistors Tr11 and Tr12 are p-channel type, the source terminal and drain terminal are reverse. The capacitor Cs is a capacity element including a parasitic capacity formed between the gate and the source of the transistor Tr12 or auxiliary capacity provided additionally between the gate and the source or the parasitic capacity and auxiliary capacity thereof.

As for the organic EL element OEL, an anode terminal (anode electrode) is connected to the contact point N12 of the above described pixel driving circuit DC and a cathode terminal (cathode electrode) is applied with a predetermined low potential voltage Vss (for example ground voltage Vgnd) is applied.

The selective line Ls is connected to the above described gate driver 120 and a selective voltage Vsel of a selective level or nonselective level is applied at a predetermined timing. The data line Ld is connected to the above described data driver 130 and applies a tone signal (tone voltage) Vdata according to the display data on the display pixel PIX set to the selective state by the above described selective voltage Vsel.

Next, the driving control operation of the display pixel PIX including the above circuit configuration is briefly described.

First, in the selective period, the selective voltage Vsel of the selective level (high level) is applied on the selective line Ls by the gate driver 120 and the transistor Tr11 turns on and is set to a selective state. Synchronizing with this timing, the tone voltage Vdata of the voltage value according to the display data is applied on the data line Ld by the data driver 130 and potential according to the tone voltage Vdata is applied to the contact point N11 (gate terminal of the transistor Tr12) through the transistor Tr11.

With this, the transistor Tr12 turns on in the conductive state according to the tone voltage Vdata and a light emission driving current of a predetermined current value passes between the drain and the source. Therefore, organic EL element OEL emits light at the luminance tone according to the tone voltage Vdata (in other words display data). At this time, the capacitor Cs connected between the gate and the source of the transistor Tr12 is accumulated with electric charge (charged) based on the tone voltage Vdata applied to the contact point N11.

Next, in the nonselective period, the selective voltage Vsel of the nonselective level (low level) is applied to the selective line Ls and the transistor Tr11 is turned off and set to the nonselective state. With this, the charge (in other words, the potential difference between the gate and the source) accumulated in the above described capacitor Cs is held and a voltage corresponding to the tone voltage Vdata is applied to the gate terminal of the transistor Tr12. Therefore, the light emitting driving current with the same current value as the above described light emitting operating state passes between the drain and the source of the transistor Tr12, and the light emitting operating state of the organic EL element OEL continues. Such driving control operation is sequentially performed on, for example, each row of all display pixels PIX aligned in two dimensions on the display panel 110 to display the desired image information.

As described above, in the display pixel PIX including the pixel driving circuit DC as shown in FIG. 7, the transistor Tr11 functions as a selective transistor and the transistor Tr12 functions as a driving transistor. Here, it is desirable that the selective transistor has high switching attribute and it is desirable that as for the driving transistor, the change of the element attribute is small and the electron mobility is high.

Therefore, when a crystalline silicon semiconductor layer is applied as the channel layer in the selective transistor and the driving transistor formed on the same substrate, the change (Vth shift) of the threshold voltage of the driving transistor is suppressed and the deterioration of element attribute is prevented and the electron mobility rises. Therefore, there is the merit of obtaining the predetermined light emission luminance by passing light emitting driving current of a desired current value at a low gate voltage through the organic EL element OEL. However, if the channel layer of the selective transistor is crystallized similarly to the driving transistor, the leak current between the drain and the source becomes large compared to when an amorphous silicon semiconductor layer is applied, and there is the demerit that the switching attribute is deteriorated.

In the present embodiment, the display pixel PIX including the pixel driving current DC shown in FIG. 7 includes a substrate configuration where, as for the selective transistor and the driving transistor formed on the same substrate, the crystallized silicon semiconductor layer is applied to only the channel layer of the driving transistor and the amorphous silicon semiconductor layer is applied to the channel layer of the selective transistor. Below, the substrate configuration applied in the display pixel of the present embodiment is described with reference to the drawings.

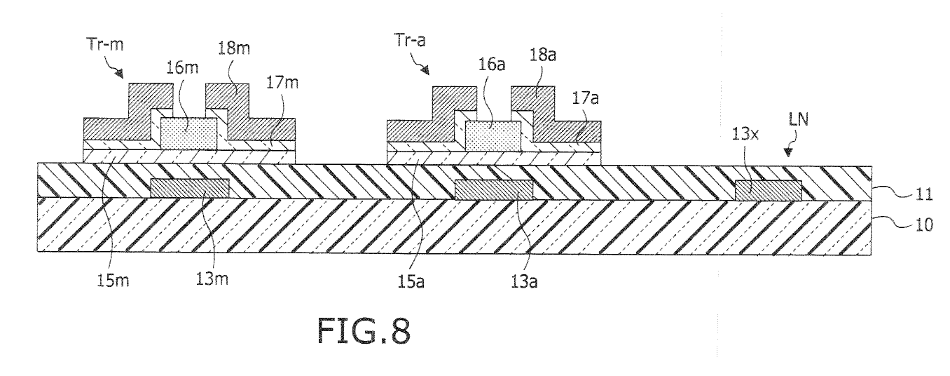

FIG. 8 is a cross sectional block diagram schematically showing a substrate configuration of the display pixel applied in the present embodiment. In order to simplify the description, in FIG. 8, the transistor including the selective transistor and the driving transistor and the line layer are shown separated and the connection between each other is omitted in the drawing. The configuration similar to the above described first embodiment is described with the same reference numerals.

As shown in FIG. 8, on one surface (top surface in the drawing) of a single insulating substrate 10, the semiconductor device of the present embodiment includes a transistor (crystalline silicon transistor; first transistor) Tr-m including a semiconductor layer including polycrystalline silicon or microcrystalline silicon, transistor (amorphous silicon transistor; second transistor) Tr-a including an amorphous silicon semiconductor layer and a line layer LN including line 13x, and the above components are provided on the same layer. The transistor Tr-m corresponds to the transistor Tr12 which functions as the driving transistor shown in FIG. 7 and the transistor Tr-a corresponds to the transistor Tr11 which functions as the selective transistor to select the driving transistor Tr12 shown in FIG. 7.

Specifically, as shown in FIG. 8, similar to the above described first embodiment (see FIG. 1), the transistor Tr-m includes a gate electrode 13m provided on a surface of one face of an insulating substrate 10, a gate insulating film 11 formed between layers, a semiconductor layer 15m including crystalline silicon provided in an area corresponding to the gate electrode 13m, a channel protecting layer 16m provided on the semiconductor layer 15m, an extrinsic semiconductor layer 17m provided extending on the semiconductor layer 15m from both edges of the channel protecting layer 16m and the source and drain electrodes 18m provided aligned on the extrinsic semiconductor layer 17m.

The transistor Tr-a includes a gate electrode 13a provided on a surface of one face of an insulating substrate 10, a gate insulating film 11 formed between layers, a semiconductor layer 15a including amorphous silicon provided in an area corresponding to the gate electrode 13a, a channel protecting layer 16a provided on the semiconductor layer 15a, an extrinsic semiconductor layer 17a provided extending on the semiconductor layer 15a from both edges of the channel protecting layer 16a and source and drain electrodes 18a.

As shown in FIG. 8, the gate electrode 13m of the transistor Tr-m, the gate electrode 13a of the transistor Tr-a and the line 13x composing the line layer LN are provided on the same layer and are covered by a common gate insulating film 11. The semiconductor layer 15m, the channel protecting layer 16m, the extrinsic semiconductor layer 17m, and the source and drain electrodes 18m of the transistor Tr-m are each provided on the same layer as the semiconductor layer 15a, the channel protecting layer 16a, the extrinsic semiconductor layer 17a, and the source and drain electrodes 18a of the transistor Tr-a, respectively. In other words, the transistor Tr-m and the transistor Tr-a are different only in terms of the property of the silicon thin film which is to be the semiconductor layer 15m and the semiconductor layer 15a and other element compositions are formed to be the same.

In FIG. 8 also, similar to FIG. 1, the source and drain electrodes 18m of the transistor Tr-m and source and drain electrodes 18a of the transistor Tr-a provided on the substrate 10 are shown in an exposed state, however in the actual product, the source and drain electrodes 18m and 18a are covered and protected by an insulating film, etc., not shown.

### (Manufacturing Method)

Next, the manufacturing method of the semiconductor device of the present embodiment is described with reference to the drawings.

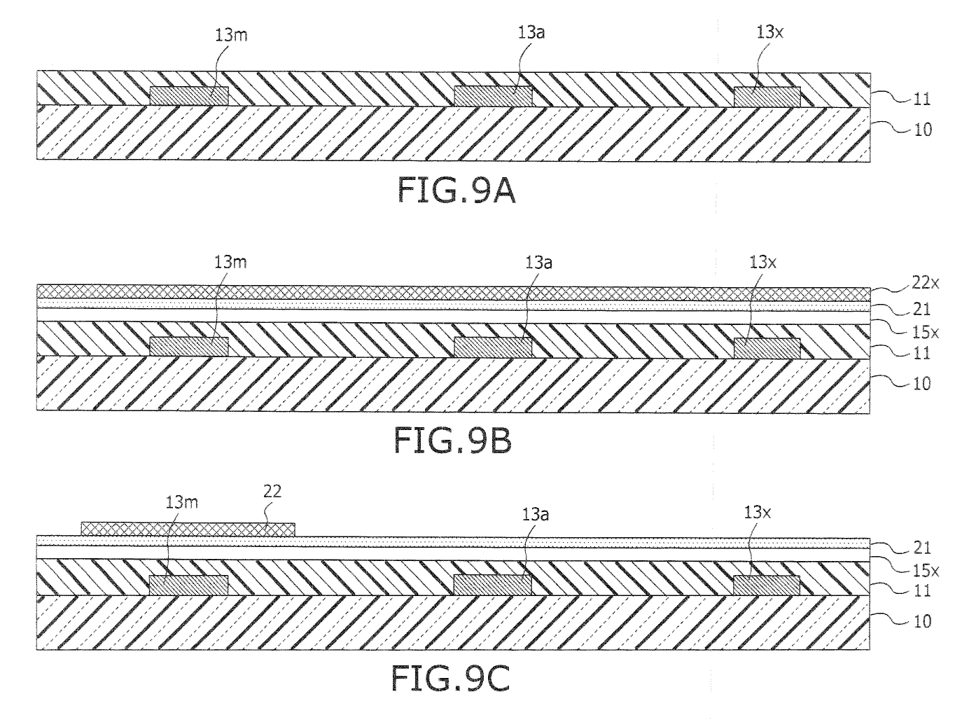

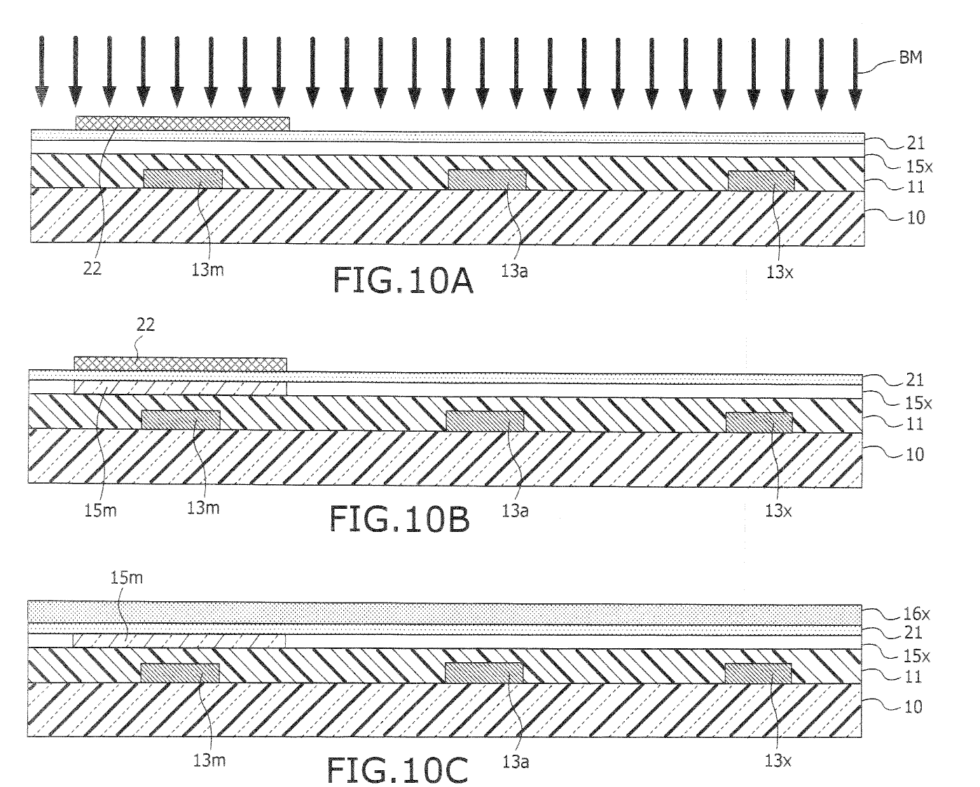

FIG. 9A to FIG. 11C are process diagrams showing a schematic cross sectional view of an example of the manufacturing method of the semiconductor device of the present embodiment. The descriptions of manufacturing steps similar to those of the above described first embodiment (see FIG. 2A to FIG. 3E) are omitted.

As shown in FIG. 9A, first, the thin film including the metal material formed on the insulating substrate 10 is patterned to form the gate electrode 13m of the transistor Tr-m, the gate electrode 13a of the transistor Tr-a, and the line 13x. The line 13x functions as at least one of the selective line Ls and data line Ld. Then, the gate insulating film 11 is formed on the entire substrate 10 and covers the gate electrode 13m, 13a and line 13x. Then, as shown in FIG. 9B, an amorphous silicon thin film 15x and a buffer layer 21 are successively formed using the plasma CVD method on the entire substrate 10 and on a further upper layer, a photothermal conversion layer 22x is formed using the sputtering method, etc.

Next, as shown in FIG. 9C, the photothermal conversion layer 22x is patterned using photolithography method so that the photothermal conversion layer 22x remains only on the area which is to be the channel layer of the transistor Tr-m (in other words, the area which includes the area where the above described gate electrode 13m is formed and which is also where the amorphous silicon film 15x is crystallized by laser anneal).

Next, as shown in FIG. 10A, the laser beam BM scans and irradiates the entire substrate 10 to heat anneal and crystallize only the amorphous silicon thin film 15x directly below the photothermal conversion layer 22. With this, as shown in FIG. 10B, the semiconductor layer 15m including a polycrystalline silicon thin film or microcrystalline silicon thin film is formed on the area on which the transistor Tr-m is formed. Here, the transistor Tr-a and the amorphous silicon thin film 15x of the forming area on the line layer LN other than the forming area of the transistor Tr-m is not crystallized and maintains the amorphous state.

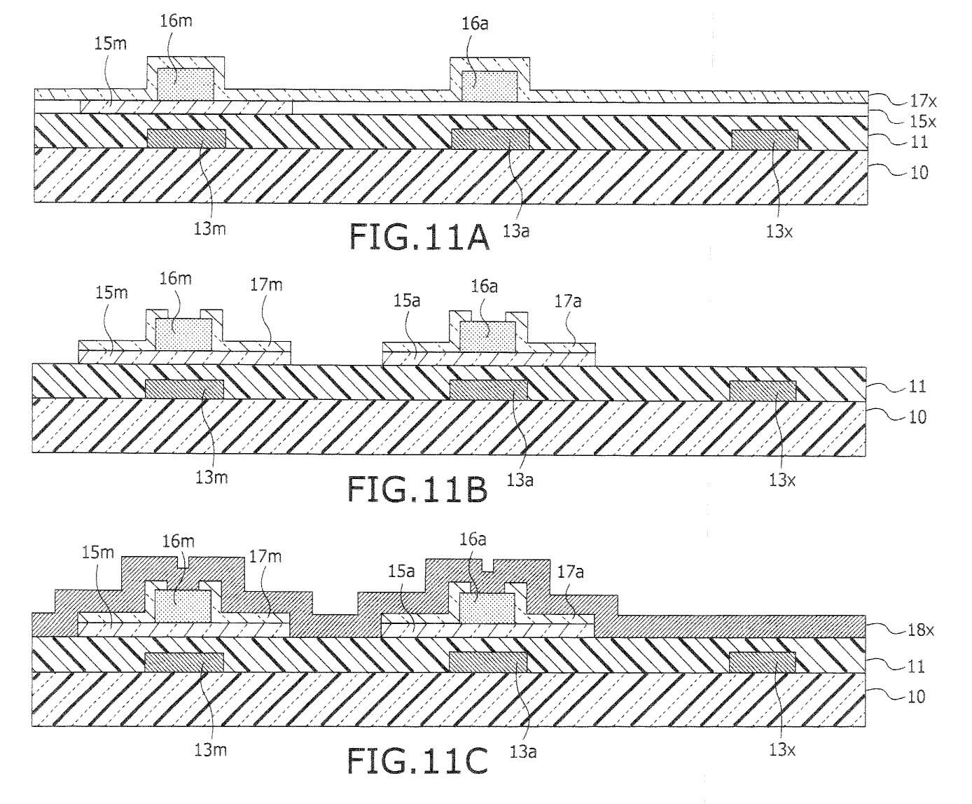

Next, as shown in FIG. 10C, after the photothermal conversion layer 22 on the buffer layer 21 is removed using the etching method, etc., the insulating layer 16x which is to be the channel protecting layer is formed on the entire substrate 10 using the plasma CVD method. Then, as shown in FIG. 11A, the insulating layer 16x and the buffer layer 21 are successively patterned using photolithography method and the channel protecting layer 16m and 16a including a laminated body of the insulating layer 16x and the buffer layer 21 are formed on the area which is to be the channel layer of the transistor Tr and which corresponds to the area on which the above described gate electrode 13m and 13a are formed. Then, the extrinsic semiconductor layer 17x to form the source and drain of the transistors Tr-m and Tr-a is formed on the entire substrate 10 using the plasma CVD method.

Next, as shown in FIG. 11B, the extrinsic semiconductor layer 17x is patterned and extrinsic semiconductor layers 17m and 17a are formed extending on the semiconductor layers 15m and 15a from both edges of the channel protecting layer 16m and 16a respectively and the amorphous silicon thin film 15x other than the semiconductor layers 15m and 15a in the area which is to be the channel layers of the transistors Tr-m and Tr-a is removed.

Next, as shown in FIG. 11C, the drain metal layer 18x to form the source and drain electrodes 18m and 18a of the transistor Tr is formed on the entire substrate 10 using a sputtering method, etc. Then, the drain metal layer 18x is patterned and as shown in FIG. 8, the source and drain electrodes 18m and 18a are formed on each of the extrinsic semiconductor layers 17m and 17a of the transistors Tr-m and Tr-a respectively.

As described above, according to the semiconductor device and the manufacturing method of the semiconductor device of the present embodiment, the transistor Tr-m including the semiconductor layer 15m including the polycrystalline silicon or microcrystalline silicon and the transistor Tr-a including the amorphous silicon semiconductor layer 15a are provided on the single substrate 10 together. The amorphous silicon thin film 15x is crystallized by a method of forming the photothermal conversion layer 22 on only the area which is to be the channel layer of the transistor Tr-m and then irradiating the laser beam BM to perform heat annealing.

With this, the semiconductor layer 15m including the crystalline silicon composing the transistor Tr-m and the semiconductor layer 15a including the amorphous silicon composing the transistor Tr-a can be formed simultaneously with one laser annealing step on the single substrate 10. Consequently, peeling and cracking of the gate insulating film 11, etc. on the area to be formed on the transistor Tr-a and the line 13x can be prevented.

With this, it is possible to efficiently heat only the amorphous silicon thin film 15x on the area on which the transistor Tr-m is formed to crystallize the area. Consequently, heating due to heat anneal in the areas where the transistor Tr-a and line 13x are formed other than the area where the transistor Tr-m is formed can be suppressed. Therefore, manufacturing yield and throughput reduction can be suppressed and the driving transistor including a crystalline silicon semiconductor and the selective transistor including the amorphous silicon conductor can be favorably formed on the same substrate.

According to a display panel including the above substrate configuration, the channel layer of the driving transistor (transistor Tr12) is formed with a crystalline silicon thin film, and thus compared to forming the channel layer with an amorphous silicon thin film, the threshold voltage Vth shift can be decreased and the element deterioration can be suppressed. Also, the electron mobility of the driving transistor (transistor Tr12) is enhanced and light emitting operation at a predetermined luminance tone at a gate voltage (tone voltage Vdata) of a low voltage can be realized. The channel layer of the selective transistor (transistor Tr11) is formed with the amorphous silicon thin film, and thus compared to forming the channel layer with a crystalline silicon thin film, the influence of the leak current can be drastically suppressed.

The present embodiment shows a circuit configuration including two transistors (transistors Tr11 and Tr12) as the pixel driving circuit DC composing the display pixel PIX, however, the present invention is not limited to such example. The present invention can include for example, three or more transistors if the pixel driving circuit DC includes at least each one of a transistor to function as the selective transistor and a transistor to function as the driving transistor.

Also, as the pixel driving circuit DC provided in the display pixel PIX, FIG. 7 shows a circuit configuration of a tone control method of a voltage specifying type where the voltage value of the tone voltage Vdata to be written in each display pixel PIX (specifically, the gate terminal of the transistor Tr12 of the pixel driving circuit DC; contact point N11) is adjusted (specified) according to the display data to control the current value of the light emitting driving current passed through the organic EL element OEL to emit light at a desired luminance tone, however the present invention is not limited to this example. In other words, the present embodiment can include a circuit configuration of a tone control method of a current specifying type where the current value of the current to be written in each display pixel PIX is adjusted (specified) according to the display data to control the current value of the light emitting driving current passed through the organic EL element OEL to emit light at a desired luminance tone.

Next, the semiconductor device and the manufacturing method of the semiconductor device of the third embodiment is described.

The above described second embodiment describes a case where a substrate configuration provided with a crystalline silicon transistor and an amorphous silicon transistor on a single substrate 10 is applied to each display pixel of the display device (display panel). In the third embodiment described below, the substrate configuration shown in the second embodiment is applied to a driver used for driving the display panel.

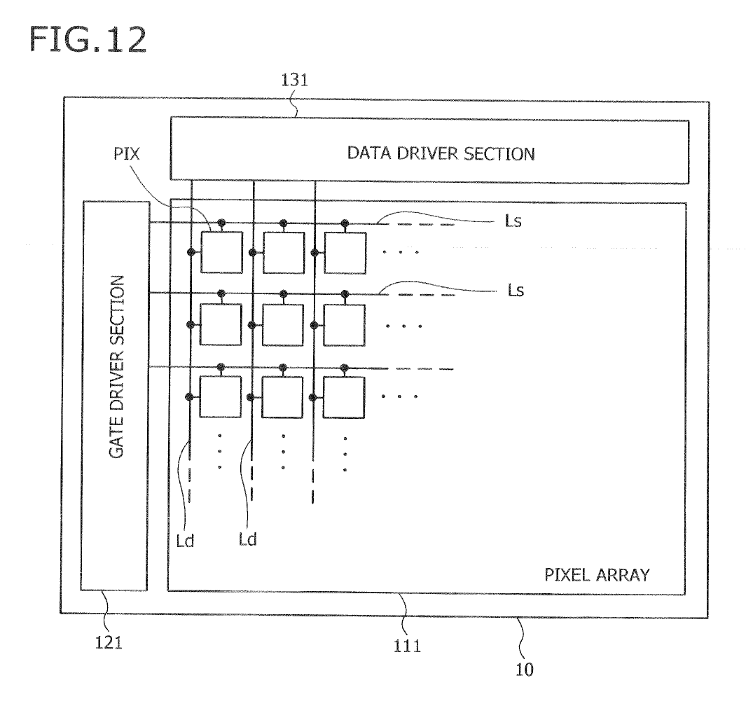

FIG. 12 is a schematic configuration diagram showing another example of a display device in which the semiconductor device of the present embodiment is applied. Here, the same reference numeral is applied to the configuration similar to the above described second embodiment and the description is simplified or omitted.

As shown in FIG. 12, the display device in which the semiconductor device of the present embodiment can be applied includes at least a pixel array (display area) 111 of a plurality of display pixels PIX arranged in two dimensions, a gate driver section 121 to set each display pixel PIX to a selective state, a data driver section 131 to provide a tone signal according to display data to each display pixel PIX, and all of these components are provided on a single substrate 10.

Here, a transistor including the crystalline (polycrystalline or microcrystalline) silicon semiconductor layer similar to the transistor Tr-m shown in the second embodiment (see FIG. 8) is used in the present embodiment as a transistor provided in the driving circuit of at least the gate driver section 121 and the data driver section 131 formed on the same substrate 10.

The manufacturing method of the semiconductor device (display device) including the above substrate configuration is described with reference to the figures showing the above described second embodiment.

First, as shown in FIG. 9A to 9C, a gate electrode 13m of a transistor Tr-m, a gate electrode 13a of a transistor Tr-a and line 13x are formed on the area on which the gate driver section 121 and the data driver section 131 are formed on the one face of the single substrate 10. Then, the gate electrodes 13m and 13a and the line 13x are covered by forming the gate insulating film 11 on the entire substrate 10. Further, on the above, the amorphous silicon thin film 15x, buffer layer 21 and the photothermal conversion layer 22x are sequentially laminated and formed.

Next, the photothermal conversion layer 22x is patterned and a photothermal conversion layer 22 is left only in the area which is to be a channel layer of the transistor provided in the driving circuit of the gate driver section 121 and the data driver section 131. Then, in this state, as shown in FIG. 10A, the laser beam BM is scanned and irradiated on the entire substrate 10 to heat anneal and crystallize only the amorphous silicon thin film 15x directly below the photothermal conversion layer 22 to form the semiconductor layer 15m including the polycrystalline silicon thin film or the microcrystalline silicon thin film as shown in FIG. 10B. At this time, the amorphous silicon thin film 15x of the area where the photothermal conversion layer 22 is not formed is not crystallized and maintains an amorphous state.

With this, the transistor including the crystalline silicon semiconductor layer is formed in the driving circuit of the gate driver section 121 and the data driver section 131 and in the area other than the above, a transistor including the amorphous silicon semiconductor layer is formed simultaneously.

According to the semiconductor device, the manufacturing method of the semiconductor device and the display device and the manufacturing method of the display device of the present embodiment, when the amorphous silicon thin film is heat annealed to be crystallized, laser anneal is performed in a state where the photothermal conversion layer is formed only on the area which is to be the channel layer of the crystalline silicon transistor and this enables crystallizing of only the amorphous silicon thin film of the area. Consequently, the crystalline silicon transistor and the amorphous silicon transistor are formed simultaneously on the same single substrate 10.

The photothermal conversion layer is not formed in the area where the amorphous silicon transistor and line layer are formed other than where the crystalline silicon transistor is formed, and heating by heat anneal can be suppressed and peeling and cracking of the insulating film, etc. formed on the gate electrode and the line can be suppressed. Therefore, in the display device in which the gate driver section 121 and the data driver section 131 to drive the pixel array 111 are provided on the single substrate 10, the crystalline silicon transistor and the amorphous silicon transistor can be suitably formed while suppressing the decrease of manufacturing yield and throughput.

Here, the display device as shown in FIG. 12, where in addition to the display pixels PIX (pixel driving circuit) arranged in the pixel array 111, the gate driver section 121, the data driver section 131, etc. to drive the display pixels PIX are formed on the single substrate 10 is described in further detail.

In the display device shown in FIG. 12, a case where the display pixel PIX includes a pixel driving circuit DC as shown in the above described second embodiment is considered (see FIG. 7). In the second embodiment, it is described that it is preferable to apply the amorphous silicon transistor or the crystalline silicon transistor according to the function as the transistors Tr11 and Tr12 of the pixel driving circuit DC due to the attribute of driving the pixel.

However, some display panels meet the necessary condition for driving the pixel even when only the amorphous silicon transistor is applied as the transistor of the pixel driving circuit DC. In the display device shown in FIG. 12, the pixel array 111, the gate driver section 121 and the data driver section 131 are all collectively formed on the single substrate 10. However, when all transistors on the substrate 10 are formed from the amorphous silicon transistor, the electron mobility is low, and the driving capability is not enough to operate the gate driver section 121 and the data driver section 131.

As a method to avoid such problems, the electron mobility can be enhanced by performing laser annealing to crystallize the channel layer of the transistor of the driver section after the patterning of the photothermal layer is formed only on the area where each driver section is formed. However, an area in the driver section where heating is unnecessary (for example, area where line is formed, etc.) is also heated, and thus there is a possibility that peeling and cracking occurs in the insulating film, etc. on the line.

Alternatively, in the semiconductor device, the manufacturing method of the semiconductor device, the display device and the manufacturing method of the display device of the present embodiment, the photothermal conversion layer used when crystallizing the amorphous silicon thin film by irradiating the laser beam on the substrate 10 is patterned to be formed so as to remain only on the area on which the channel layer of the transistor of the driving circuit is provided in at least the gate driver section 121 and the data driver section 131. Then, the laser beam is irradiated and the amorphous silicon thin film is crystallized to form the crystalline silicon transistor.

With this, the crystalline silicon transistor and the amorphous silicon transistor can be formed simultaneously on the single substrate and the heating of the area other than where the crystalline silicon transistor is formed on the area where the line layer, etc. is formed can be suppressed, and the peeling and cracking of the film on the line layer can be suppressed, and reduction of manufacturing yield and throughput can be suppressed.

In the present embodiment, a case of applying the technique of the present invention to the driving circuit of the gate driver section 121 and the data driver section 131 of the display device when the amorphous silicon transistor is applied to the pixel driving circuit of the display pixel PIX is described, however, the present invention is not limited to such example. In other words, in addition to the driving circuit of the gate driver section 121 and the data driver section 131, the crystalline silicon transistor can be applied to the driving transistor of the pixel driving circuit of the display pixel PIX arranged on the display panel (pixel array) as shown in the above described second embodiment to apply the technique of the present invention.

Also, in the above described embodiments, a case which includes an element configuration of an etching stopper type as the transistor is described, however, the present invention is not limited to such example. Alternatively, an example including the element configuration of a channel etching type can achieve the same effects as the above. Further, in the above described embodiments, a case which includes an element configuration of an invert staggered type as the transistor is described, however, the present invention is not limited to such example and an element configuration of a staggered type can be included.

### Second Example

Another example of a preferred embodiment for carrying out the present invention is described below with reference to the attached drawings. The embodiments described below include various technically preferable limitations for carrying out the present invention, however, the scope of the invention is not limited to the embodiments described below and the illustrated examples.

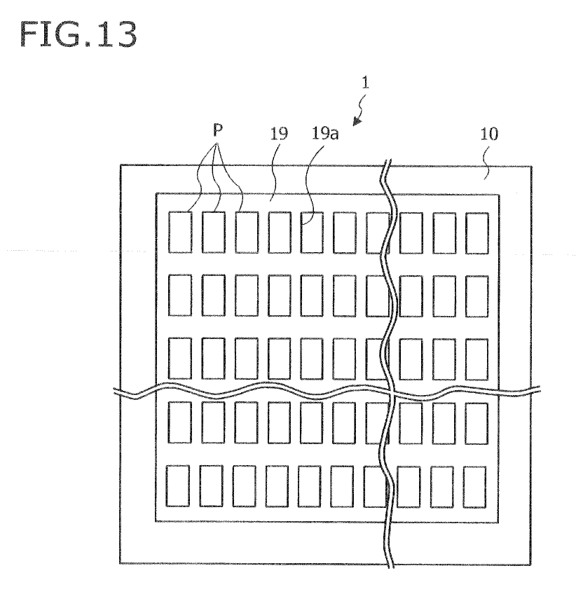

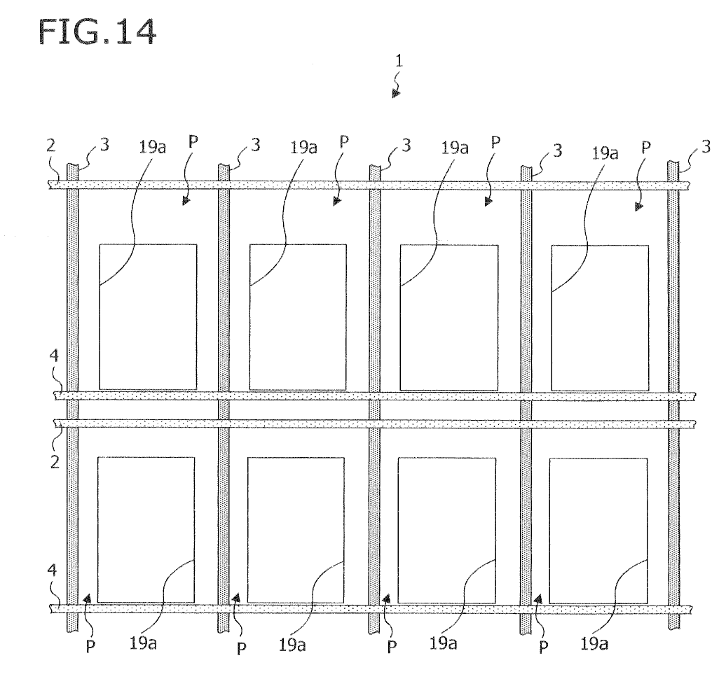

FIG. 13 is a planar view showing an arrangement of a plurality of pixels P on an EL panel 1 which is a light emitting display device (display panel) and FIG. 14 is a planar view showing a schematic configuration of the EL panel 1.

As shown in FIG. 13 and FIG. 14, a plurality of pixels P each emitting light in the color of R (red), G (green) and B (blue) are arranged in a matrix of a predetermined pattern on the EL panel 1.

On the EL panel 1, a plurality of scanning lines 2 are arranged so as to be substantially parallel to each other along the row direction and a plurality of signal lines 3 are arranged so as to be substantially parallel to each other along the column direction to be substantially orthogonal to the scanning line 2 in a planar view. A voltage supplying line 4 is provided between adjacent scanning lines 2 along the scanning line 2. An area surrounded by each scanning line 2, two adjacent signal lines 3 and each voltage supplying line 4 corresponds to the pixel P.

Also, a bank 19 to be a grid like dividing wall is provided so as to cover above the scanning line 2, the signal line 3, and the voltage supplying line 4 on the EL panel 1. A plurality of openings 19a in a substantial rectangular shape surrounded by the bank 19 is formed for each pixel P, and a predetermined carrier transporting layer (later described hole injecting layer 8b and light emitting layer 8c) is provided in the opening 19a and is to be a light emitting area of the pixel P. The carrier transporting layer is a layer to transport a hole or electron by applying voltage.

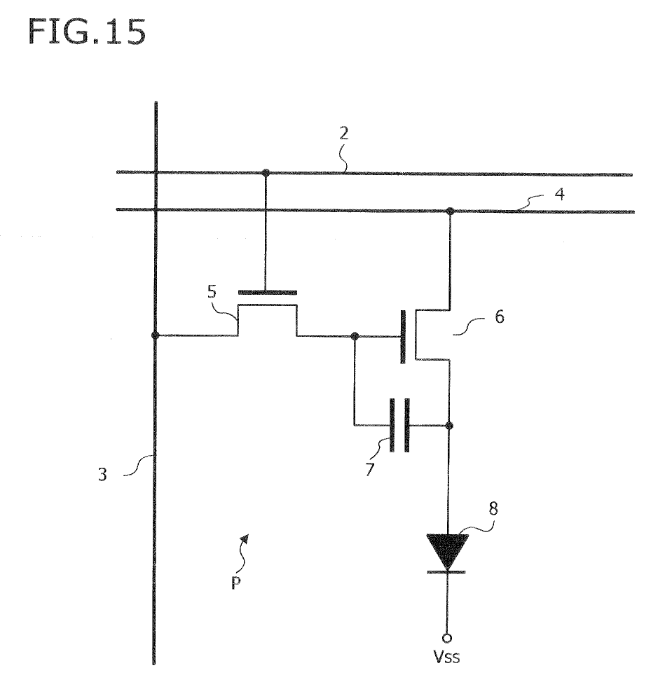

FIG. 15 is a circuit diagram showing a circuit corresponding to a pixel of the EL panel 1 operating in an active matrix driving method.

As shown in FIG. 15, the EL panel 1 is provided with a scanning line 2, a signal line 3 intersecting the scanning line 2 and a voltage supplying line 4 along the scanning line 2 and each pixel P of the EL panel 1 is provided with a switch transistor 5 which is a transistor, a driving transistor 6 which is a transistor, a capacitor 7 and a light emitting element 8 to function as a display element such as an organic EL element, etc.

In each pixel P, the gate of the switch transistor 5 is connected to the scanning line 2, either one of the drain or source of the switch transistor 5 is connected to the signal line 3, the other drain or source of the switch transistor 5 is connected to one of the electrode of the capacitor 7 and the gate of the driving transistor 6. Either one of the source or the drain of the driving transistor 6 is connected to the voltage supplying line 4, and the other source or drain of the driving transistor 6 is connected to the other electrode of the capacitor 7 and an anode of the light emitting element 8. The cathode of the light emitting element 8 of all pixels P are maintained at a certain voltage Vss (for example, grounded).

Each scanning line 2 is connected to the scanning driver at the circumference of the EL panel 1, each voltage supplying line 4 is connected to a certain voltage source or a driver to suitably output a voltage signal, each signal line 3 is connected to a data driver and the driver drives the EL panel 1 with an active matrix driving method. Predetermined voltage is supplied to the voltage supplying line 4 by a certain voltage source or driver.

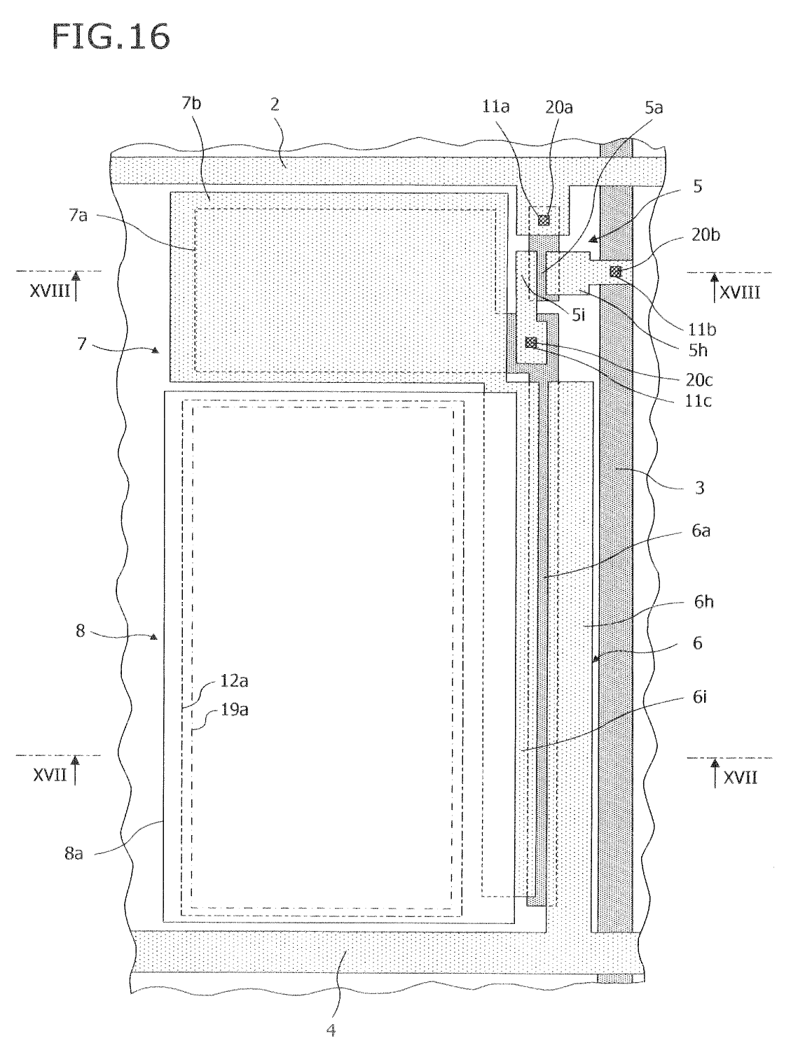

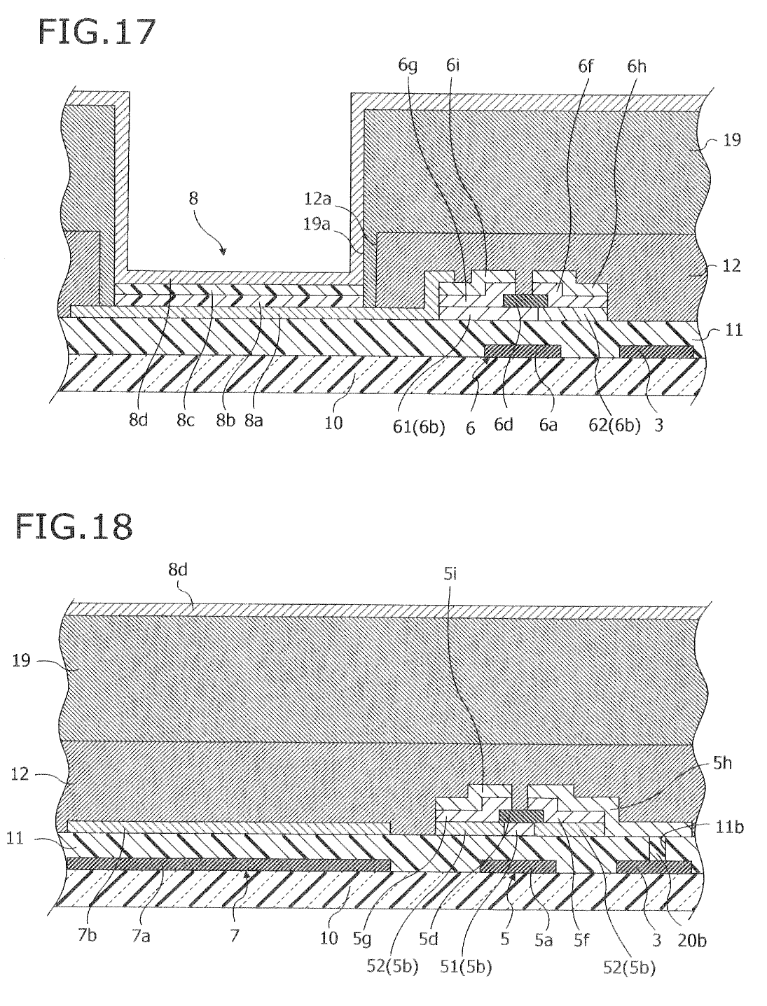

Next, the EL panel 1 and the circuit configuration of the pixel P are described with reference to FIG. 16 to FIG. 18. FIG. 16 is a planar view corresponding to one pixel P of the EL panel 1, FIG. 17 is a cross sectional view of a plane taken along line XVII-XVII shown in FIG. 16, FIG. 18 is a cross sectional view of a plane taken along line XVIII-XVIII shown in FIG. 16.

FIG. 16 mainly shows electrodes and line.

As shown in FIG. 16, the switch transistor 5 and the driving transistor 6 are arranged along the signal line 3, the capacitor 7 is positioned near the switch transistor 5, and the light emitting element 8 is positioned near the driving transistor 6. The switch transistor 5, the driving transistor 6, the capacitor 7 and the light emitting element 8 are positioned between the scanning line 2 and the voltage supplying line 4.

As shown in FIG. 16 to FIG. 18, a gate insulating film 11 is formed to be a gate insulating film on one face of the substrate 10 and a second insulating film 12 is formed on the gate insulating film 11. The signal line 3 is formed between the gate insulating film 11 and the substrate 10 and the scanning line 2 and the voltage supplying line 4 are formed between the gate insulating film 11 and the second insulating film 12.

As shown in FIG. 16 and FIG. 18, the switch transistor 5 is a transistor with an invert staggered configuration. The switch transistor 5 includes a gate electrode 5a, a semiconductor layer 5b, a channel protecting layer 5d, extrinsic semiconductor layers 5f and 5g, a drain electrode 5h, a source electrode 5i and the like.

The gate electrode 5a is formed between the substrate 10 and the gate insulating film 11. For example, the gate electrode 5a includes a Cr film, an Al film, a Cr/Al laminated film, an AlTi alloy film or an AlTiNd alloy film. Also, a gate insulating film 11 with insulation properties is formed on the gate electrode 5a and the gate insulating film 11 covers the gate electrode 5a.

For example, the gate insulating film 11 is light permeable and includes silicon nitride or silicon oxide. An intrinsic semiconductor layer 5b is formed in a position corresponding to the gate electrode 5a on the gate insulating film 11 and the semiconductor layer 5b and the gate electrode 5a face each other with a gate insulating film 11 in between.

For example, the semiconductor layer 5b is a single layer film including a microcrystalline silicon area 51 including microcrystalline silicon and an amorphous silicon area 52 including amorphous silicon and a channel is formed in the semiconductor layer 5b. The microcrystalline silicon area 51 is positioned above the gate electrode 5a in the semiconductor layer 5b and both sides of the microcrystalline silicon area 51 are each amorphous silicon areas 52.

The channel protecting layer 5d with insulating properties is formed on a center section of the semiconductor layer 5b. The channel protecting layer 5d covers the microcrystalline silicon area 51 in the semiconductor layer 5b and both edge sides of the channel protecting layer 5d cover a portion of the amorphous silicon area 52 on the microcrystalline silicon area 51 side. For example, the channel protecting layer 5d includes silicon nitride or silicon oxide.

The extrinsic semiconductor layer 5f is formed on the amorphous silicon area 52 at one edge side of the semiconductor layer 5b so as to overlap with a portion of the channel protecting layer 5d, and the extrinsic semiconductor layer 5g is formed on the amorphous silicon area 52 at the other edge side of the semiconductor layer 5b so as to overlap with a portion of the channel protecting layer 5d. The extrinsic semiconductor layers 5f and 5g are formed separated from each other on each edge side of the semiconductor layer 5b, and the extrinsic semiconductor layers 5f and 5g are formed in a position on the semiconductor layer 5b facing each other with the channel protecting layer 5d in between. The extrinsic semiconductor layers 5f and 5g are n-type semiconductors, however it is not limited to this and can be p-type semiconductors.

The drain electrode 5h is formed on the extrinsic semiconductor layer 5f. The source electrode 5i is formed on the extrinsic semiconductor layer 5g. For example, the drain electrode 5h and the source electrode 5i include a Cr film, an Al film, a Cr/Al laminated film, an AlTi alloy film or an AlTiNd alloy film.

The second insulating film 12 with insulating properties is formed on the channel protecting layer 5d, the drain electrode 5h and the source electrode 5i to be a protecting film, and the channel protecting layer 5d, the drain electrode 5h and the source electrode 5i are covered by the second insulating film 12. The switch transistor 5 is covered by the second insulating film 12. For example, the second insulating film 12 includes silicon nitride or silicon oxide.

The switch transistor 5 used as the driving element in the EL panel 1 includes the semiconductor layer 5b in which both edge sides of the microcrystalline silicon area 51 are amorphous silicon areas 52, as shown in FIG. 18. The amorphous silicon areas 52 are positioned on both sides of the microcrystalline silicon area 51 in a direction where the extrinsic semiconductor layers 5f and 5g are facing each other with the channel protecting layer 5d in between.

The channel protecting layer 5d of the switch transistor 5 covers the microcrystalline silicon area 51 on the semiconductor layer 5b and covers a portion of the amorphous silicon area 52 on the microcrystalline silicon area 51 side at both edge sides of the channel protecting layers 5d. The amorphous silicon area 52 in the semiconductor layer 5b is covered with extrinsic semiconductor layers 5f and 5g.

In other words, the microcrystalline silicon area 51 of the semiconductor layer 5b is positioned on a lower face side of the channel protecting layer 5d and the amorphous silicon area 52 of the semiconductor layer 5b is positioned on a lower face side of the extrinsic semiconductor layers 5f and 5g on both sides of the microcrystalline silicon area 51 and the border between both edges of the microcrystalline silicon area 51 and the amorphous silicon area 52 is positioned on a lower face side of the channel protecting layer 5d.

The length of the channel protecting layer 5d positioned above the gate electrode 5a along the direction in which the pair of extrinsic semiconductor layers 5f and 5g face each other is longer than the length of the microcrystalline silicon area 51 portion of the semiconductor layer 5b and formed to be no longer than the gate electrode 5a.

The semiconductor layer 5b which is to be the channel area includes the microcrystalline silicon area 51 and the amorphous silicon area 52. The extrinsic semiconductor layers 5f and 5g which are to be the source/drain area are in contact with the amorphous silicon area 52 of the semiconductor layer 5b, and are not in direct contact with the microcrystalline silicon area 51.

The extrinsic semiconductor layers 5f and 5g are not in contact with the microcrystalline silicon area 51 and are in contact with the amorphous silicon area 52 to be electrically connected with the semiconductor layer 5b. Consequently, compared to when the extrinsic semiconductor layers 5f and 5g are in contact with the microcrystalline silicon area 51, the leak current is not generated easily.

As shown in FIG. 15 and FIG. 16, in the switch transistor 5, the drain electrode 5h is connected to the signal line 3, the source electrode 5i is connected to the gate electrode 6a of the driving transistor 6, and the direction of the current between the source and the drain in switching to allow the light emitting element 8 to emit light is not fixed. However, since both extrinsic semiconductors 5f and 5g are not connected to the microcrystalline silicon area 51, electron-hole pair generation due to the microcrystalline silicon is suppressed.

With this, suitable current control where generation of leak current is suppressed is possible in a case where current from the drain electrode 5h and the extrinsic semiconductor layer 5f to the source electrode 5i and the extrinsic semiconductor layer 5g (current from one amorphous silicon area 52 through the microcrystalline silicon area 51 to the other amorphous silicon area 52) flows to the semiconductor layer 5b and in a case where current from the source electrode 5i and the extrinsic semiconductor layer 5g to the drain electrode 5h and the extrinsic semiconductor layer 5f (current from the other amorphous silicon area 52 through the microcrystalline silicon area 51 to the one amorphous silicon area 52) flows to the semiconductor layer 5b.

As shown in FIG. 16 and FIG. 17, the driving transistor 6 is a transistor with an invert staggered configuration. The driving transistor 6 includes a gate electrode 6a, a semiconductor layer 6b, a channel protecting layer 6d, extrinsic semiconductor layers 6f and 6g, a drain electrode 6h, a source electrode 6i and the like.

For example, the gate electrode 6a includes a Cr film, an Al film, a Cr/Al laminated film, an AlTi alloy film or an AlTiNd alloy film and similar to the gate electrode 5a, the gate electrode 6a is formed between the substrate 10 and the insulating film 11. For example, the gate electrode 6a is covered with a gate insulating film 11 including silicon nitride or silicon oxide.

The semiconductor layer 6b, on which a channel is formed, is provided at a position corresponding to the gate electrode 6a on the gate insulating film 11. The semiconductor layer 6b faces the gate electrode 6a with the gate insulating film 11 in between.

For example, the semiconductor layer 6b is a single layer film including a microcrystalline silicon area 61 including microcrystalline silicon and an amorphous silicon area 62 including amorphous silicon. The microcrystalline silicon area 61 is positioned in an area of the semiconductor layer 6b from the upper center side of the gate electrode 6a to the extrinsic semiconductor layer 6g side and the amorphous silicon area 62 is positioned in an area of the semiconductor layer 6b from the upper edge side of the gate electrode 6a to the extrinsic semiconductor layer 6f side.

A channel protecting layer 6d with insulating properties is formed on the center section of the semiconductor layer 6b. The channel protecting layer 6d covers the microcrystalline silicon area 61 portion positioned in the center side of the semiconductor layer 6b and one edge side of the channel protecting layer 6d covers a portion of the amorphous silicon area 62 on the microcrystalline silicon area 61 side. For example, the channel protecting layer 6d includes silicon nitride or silicon oxide.

The extrinsic semiconductor layer 6f is formed on the amorphous silicon area 62 on the one edge side of the semiconductor layer 6b so as to overlap a portion of the channel protecting layer 6d. The extrinsic semiconductor layer 6g is formed on the microcrystalline silicon area 61 of the other edge side of the semiconductor layer 6b so as to overlap a portion of the channel protecting layer 6d. The extrinsic semiconductor layers 6f and 6g are formed separated from each other on each edge side of the semiconductor layer 6b and the extrinsic semiconductor layers 6f and 6g are formed in a position on the semiconductor layer 6b facing each other with the channel protecting layer 6d in between. The extrinsic semiconductor layers 6f and 6g are n-type semiconductors, however it is not limited to this and can be p-type semiconductors.

The drain electrode 6h is formed on the extrinsic semiconductor layer 6f. The source electrode 6i is formed on the extrinsic semiconductor layer 6g. For example, the drain electrode 6h and the source electrode 6i include a Cr film, an Al film, a Cr/Al laminating film, an AlTi alloy film, or an AlTiNd alloy film.

A second insulating film 12 with insulating properties is formed on the channel protecting layer 6d, the drain electrode 6h and the source electrode 6i, and the channel protecting layer 6d, the drain electrode 6h and the source electrode 6i are covered by the second insulating film 12. The driving transistor 6 is covered by the second insulating film 12.

As described above, the driving transistor 6 used as the driving element in the EL panel 1 includes a semiconductor layer 6b including the microcrystalline silicon area 61 and the amorphous silicon area 62 as shown in FIG. 17. The microcrystalline silicon area 61 is positioned from the channel protecting layer 6d to the lower face of the extrinsic semiconductor layer 6g and the amorphous silicon area 62 is provided from the edge side of the channel protecting layer 6d to the lower face of the extrinsic semiconductor layer 6f.

The channel protecting layer 6d of the driving transistor 6 covers the microcrystalline silicon area 61 portion positioned above the gate electrode 6a and also covers a portion of the amorphous silicon area 62 on the microcrystalline silicon area 61 side (drain electrode 6h side) at the edge of the channel protecting layer 6d. The microcrystalline silicon area 61 portion not covered by the channel protecting layer 6d is covered by the extrinsic semiconductor layer 6g and the amorphous silicon area 62 in the semiconductor layer 6b is covered with the extrinsic semiconductor layer 6f.

The microcrystalline silicon area 61 in the semiconductor layer 6b is positioned from the lower face side of the channel protecting layer 6d to the lower face side of the extrinsic semiconductor layer 6g which is one of the pair of extrinsic semiconductor layers and the amorphous silicon layer 62 in the semiconductor layer 6b is positioned in the lower face side of the extrinsic semiconductor layer 6f which is the other of the pair of extrinsic semiconductor layers and the border between the microcrystalline silicon area 61 and the amorphous silicon area 62 is positioned in the lower face side of the channel protecting layer 6d. In the semiconductor layer 6b, the length of the microcrystalline silicon area 61 portion along the direction in which the pair of extrinsic semiconductor layers 6f and 6g face each other is longer than the length of the amorphous silicon area 62 portion.

The border between the microcrystalline silicon area 61 and the amorphous silicon area 62 in the semiconductor layer 6b which is to be the channel area is positioned in the lower face side of the channel protecting layer 6d. The extrinsic semiconductor layer 6f which is to be the source/drain area is in contact with the amorphous silicon area 62 of the semiconductor layer 6b and the extrinsic semiconductor layer 6g which is to be the source/drain area is in contact with the microcrystalline silicon area 61 of the semiconductor layer 6b.

The extrinsic semiconductor layer 6f is not in contact with the microcrystalline silicon area 61 and is in contact with the amorphous silicon area 62 to be electrically connected to the semiconductor layer 6b, and compared to when the extrinsic semiconductor layer 6f is in contact with the microcrystalline silicon area 61, the leak current is not generated easily.

As shown in FIG. 15 and FIG. 16, in the driving transistor 6, the drain electrode 6h is connected to the voltage supplying line 4, the source electrode 6i is connected to the light emitting element 8 and the direction of the current between the source and the drain in switching driving to allow the light emitting element 8 to emit light is fixed to one direction from the amorphous silicon area 62 to the microcrystalline silicon area 61. Also, the extrinsic semiconductor layer 6f is not in contact with the microcrystalline silicon area 61. Consequently, electron-hole pair generation due to microcrystalline silicon can be suppressed.

With this, suitable current control where generation of leak current is suppressed is possible when the current from the drain electrode 6h and the extrinsic semiconductor layer 6f to the source electrode 6i and the extrinsic semiconductor layer 6g (current from the amorphous silicon area 62 to the microcrystalline silicon area 61) flows to the semiconductor layer 6b.

In a driving transistor 6 where the direction of the current is fixed, if the semiconductor layer 6b portion in contact with the extrinsic semiconductor layer 6f which is to be the upstream side of the current is the amorphous silicon area 62, the generation of leak current can be suppressed. Also, since the length of the microcrystalline silicon area 61 portion is longer than the length of the amorphous silicon area 62 portion in the current direction, the current flows more easily in the transistor.

In other words, even if the transistor size is made small, a larger current can be passed through to enhance light emitting luminance of the light emitting element 8 and consequently, the display performance of the EL panel 1 becomes favorable.

The capacitor 7 is connected between the gate electrode 6a and the source electrode 6i of the driving transistor 6 and as shown in FIG. 16 and FIG. 18, one electrode 7a is formed between the substrate 10 and the gate insulating film 11 and the other electrode 7b is formed between the gate insulating film 11 and the second insulating film 12 and the electrode 7a and the electrode 7b face each other with the gate insulating film 11 which is the dielectric material in between.

The signal line 3, the electrode 7a of the capacitor 7, the gate electrode 5a of the switch transistor 5 and the gate electrode 6a of the driving transistor 6 are collectively formed by processing and shaping a conductive metallic film by photolithography method, etching method, etc. formed on one face of the substrate 10.

The scanning line 2, the voltage supplying line 4, the electrode 7b of the capacitor 7, the drain electrode 5h and the source electrode 5i of the switch transistor 5 and the drain electrode 6h and the source electrode 6i of the driving transistor 6 are formed by processing and shaping a conductive metallic film by photolithography method, etching method, etc. formed on one face of the gate insulating film 11.

As for the gate insulating film 11, a contact hole 11a is formed in an area where the gate electrode 5a and the scanning line 2 overlap, a contact hole 11b is formed in an area where the drain electrode 5h and the signal line 3 overlap, a contact hole 11c is formed in an area where the gate electrode 6a and the source electrode 5i overlap, and contact plugs 20a to 20c are each embedded in the contact holes 11a to 11c respectively. The gate electrode 5a of the switch transistor 5 and the scanning line 2 are electrically continuous by the contact plug 20a, the drain electrode 5h of the switch transistor 5 and the signal line 3 are electrically continuous by the contact plug 20b, the source electrode 5i of the switch transistor 5 and the electrode 7a of the capacitor 7 are electrically continuous by the contact plug 20c and the source electrode 5i of the switch transistor 5 and the gate electrode 6a of the driving transistor 6 are electrically continuous by the contact plug 20c. Alternatively, the scanning line 2 can be in direct contact with the gate electrode 5a, the drain electrode 5h can be in contact with signal line 3 and the source electrode 5i can be in contact with the gate electrode 6a without the contact plugs 20a to 20c.

The gate electrode 6a of the driving transistor 6 continues to the electrode 7a of the capacitor 7 as one, the drain electrode 6h of the driving transistor 6 continues to the voltage supplying line 4 as one and the source electrode 6i of the driving transistor 6 continues to the electrode 7b of the capacitor 7 as one.

The pixel electrode 8a is provided on the substrate 10 through the gate insulating film 11 and is independently formed with respect to each pixel P. The pixel electrode 8a is a transparent electrode including, for example, tin dope indium oxide (ITO), zinc dope indium oxide, indium oxide (In₂O₃), tin oxide (SnO2), zinc oxide (ZnO), cadmium tin oxide (CTO). A portion of the pixel electrode 8a overlaps with the source electrode 6i of the driving transistor 6 and the pixel electrode 8a is connected to the source electrode 6i.

As shown in FIG. 16 and FIG. 17, the second insulating film 12 is formed so as to cover the scanning line 2, the signal line 3, the voltage supplying line 4, the switch transistor 5, the driving transistor 6, the circumference of the pixel electrode 8a, the electrode 7b of the capacitor 7 and the gate insulating film 11. The second insulating film 12 is formed with an opening 12a to expose a center section of each pixel electrode 8a. Therefore, the second insulating film 12 is formed in a grid shape from a planar view.

The scanning line 2, the signal line 3, the voltage supplying line 4, the switch transistor 5, the driving transistor 6, the capacitor 7, the pixel electrode 8a, and the second insulating film 12 are formed on the surface of the substrate 10 to compose a panel which is to be a transistor array panel.

As shown in FIG. 16 and FIG. 17, the light emitting element 8 includes a pixel electrode 8a as a first electrode to be an anode, a hole injecting layer 8b as a compound film formed on the pixel electrode 8a, a light emitting layer 8c which is a compound film formed on the hole injecting layer 8b, and an opposite electrode 8d as a second electrode formed on the light emitting layer 8c. The opposite electrode 8d is a single electrode common to all pixels P and is formed continuing through all pixels P.

The hole injecting layer 8b is a functional layer including, for example, PEDOT (poly (ethylenedioxy) thiophene) which is a conductive polymer and PSS (polystyrene sulfonate) which is a dopant and is a carrier inserting layer to insert a hole from the pixel electrode 8a to the light emitting layer 8c.

The light emitting layer 8c includes any one of a light emitting material of R (red), G (green), and B (blue) with respect to each pixel P, and includes, for example, light emitting material of polyfluorene series or light emitting material of poly (phenylene vinylene) series. The light emitting layer 8c is a layer which emits light when the electron supplied from the opposite electrode 8d and the hole injected from the hole injecting layer 8 recombine. Therefore, the light emitting materials of the light emitting layer 8c among the pixel P emitting light of R (red), the pixel P emitting light of G (green), and the pixel P emitting light of B (blue) are different from each other. The pattern of the pixels P of R (red), G (green), B (blue) can be a delta arrangement or a stripe pattern where pixels of the same color are arranged in the vertical direction.

The opposite electrode 8d is formed from material with a lower work function than the pixel electrode 8a, and is formed from a single type or alloy including at least one of, for example, indium, magnesium, calcium, lithium, barium, or rare earth metal.

The opposite electrode 8d is an electrode common to all pixels P, and covers a later described bank 19 with the compound film such as the light emitting layer 8c, etc.

As described above, the second insulating film 12 and the bank 19 divides the light emitting layer 8c which is to be the light emitting section with respect to each pixel P.

Then, in the opening 19a, the hole injecting layer 8b and the light emitting layer 8c as carrier transporting layers are laminated on the pixel electrode 8a.

Specifically, the bank 19 functions as a dividing wall so that the liquid where material which is to be the hole injecting layer 8b and light emitting layer 8c are dissolved or dispersed in the solvent does not run out to the adjacent pixel P when the hole injecting layer 8b and the light emitting layer 8c is formed by a wet type method.

For example, as shown in FIG. 17, the opening 19a is formed to the inner side than the opening 12a of the second insulating film 12 on the bank 19 provided on the second insulating film 12.

Then, a liquid including material which is to be the hole injecting layer 8b is applied on each pixel electrode 8a surrounded by each opening 19a and the liquid is heated with respect to each substrate 10 and dried to form the compound film which is to be the hole injecting layer 8b which is a first carrier transporting layer.

Further, a liquid including material which is to be the light emitting layer 8c is applied on each hole injecting layer 8b surrounded by each opening 19a and the liquid is heated with respect to each substrate 10 and dried to form the compound film which is to be the light emitting layer 8c which is the second carrier transporting layer.

The opposite electrode 8d is formed so as to cover the light emitting layer 8c and the bank 19.

In the EL panel 1, the pixel electrode 8a, the substrate 10 and the gate insulating film 11 are transparent, and the light emitted from the light emitting layer 8c transmits through the pixel electrode 8a, the gate insulating film 11 and the substrate 10 to exit. Therefore, the back face of the substrate is the display face.

Instead of the substrate 10 side, the opposite side can be the display face. In this case, the opposite electrode 8d is the transparent electrode, the pixel electrode 8a is the reflecting electrode and the light emitted from the light emitting layer 8c transmits through the opposite electrode 8d and exits.

This EL panel 1 is driven and emits light as described in the following.

While in a state where voltage of a predetermined level is applied to all of the voltage supplying lines 4, when the scanning driver sequentially applies voltage to the scanning lines 2, the scanning lines 2 are sequentially selected.

When the data driver applies voltage at a level according to the tone to all of the signal lines 3 while the scanning lines 2 are selected, since the switch transistor 5 corresponding to the selected scanning line 2 is on, voltage at a level according to the tone is applied to the gate electrode 6a of the driving transistor 6.

According to the voltage applied to the gate electrode 6a of the driving transistor 6, the potential difference is determined between the gate electrode 6a and the source electrode 6i of the driving transistor 6, the size of the drain-source current in the driving transistor 6 is determined and the light emitting element 8 emits light at a luminance according to the drain-source current.

Then, when the selection of the scanning lines 2 is released, the switch transistor 5 is off, and electric charge according to the voltage applied to the gate electrode 6a of the driving transistor 6 is charged in the capacitor 7, and the potential difference between the gate electrode 6a and the source electrode 6i of the driving transistor 6 is maintained.

Therefore, the driving transistor 6 continues to pass the drain-source current with the current value which is the same as when selected and maintains the luminance of the light emitting element 8.

Next, a method of manufacturing of the transistor used as the driving element in the EL panel 1 of the present embodiment is described with reference to a switch transistor 5 as an example.

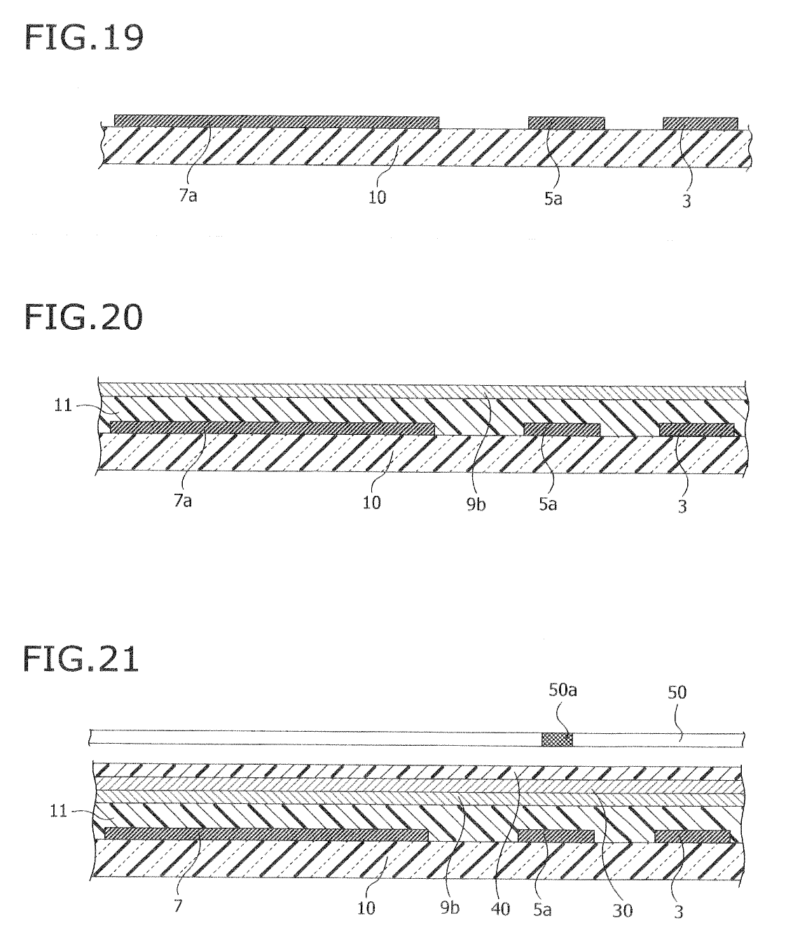

First, a gate metal layer is deposited on the substrate 10 with sputtering method, and by patterning with a photolithography method, etching method, etc., a gate electrode 5a is formed as shown in FIG. 19 (gate forming step).

Together with the gate electrode 5a, the gate electrode 6a of the driving transistor 6, signal line 3, and electrode 7a of the capacitor 7 are formed on the substrate 10 (see FIG. 17, FIG. 18).

Next, as shown in FIG. 20, with plasma CVD, the gate insulating film 11 such as silicon nitride and the semiconductor layer 9b including amorphous silicon which is to be the semiconductor layer 5 are successively deposited and two layers are formed (two layer forming step).

Next, as shown in FIG. 21, a photothermal conversion layer 30 and a photoresist layer 40 of the positive type are successively formed on the semiconductor layer 9b. The photothermal conversion layer 30 is a layer including material which can convert light emitted on the photothermal conversion layer 30 to heat (photothermal conversion material) and material such as diamond like carbon (DLC), molybdenum (Mo), etc. can be used. A buffer layer 21 as shown in FIG. 2C can be placed between the semiconductor layer 9b and the photothermal conversion layer 30.

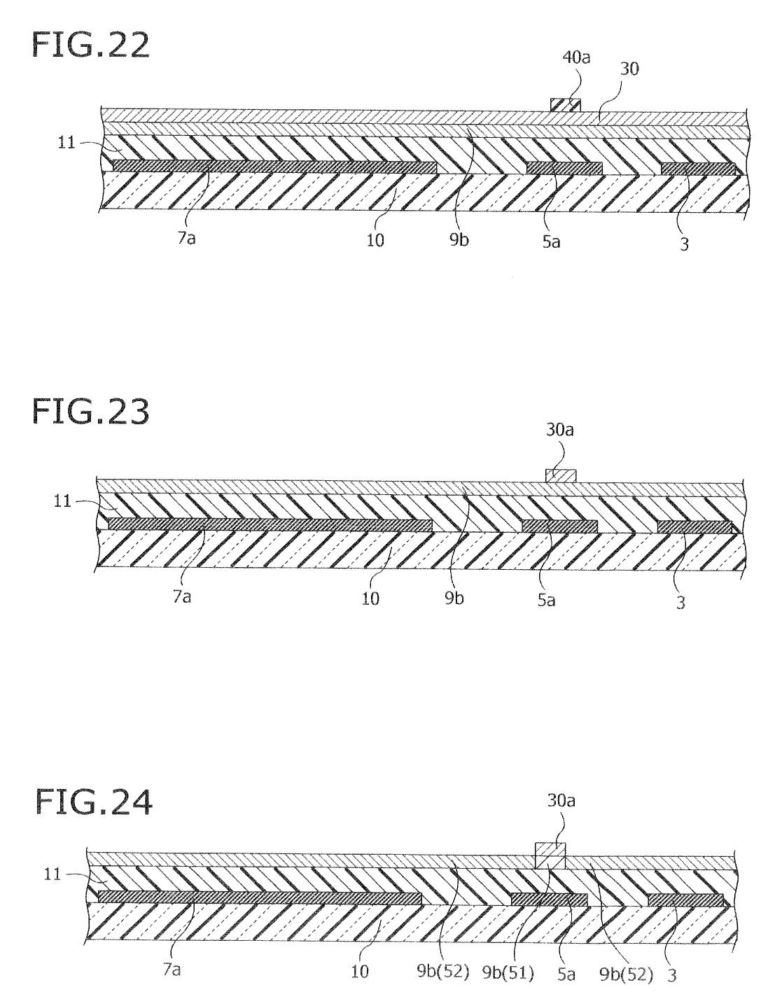

Further, as shown in FIG. 21, a photomask 50 including a mask section 50a is placed on the photoresist layer 40 and patterning is performed by photolithography method, etching method, and the like to form the resist 40a on the photothermal conversion layer 30 above the gate electrode 5a as shown in FIG. 22. The size of the resist 40a corresponds to the range where the microcrystalline silicon area is formed in the semiconductor layer 5b. A resist corresponding to the range where the microcrystalline silicon area is formed in the semiconductor layer 6b is also formed on the photothermal conversion layer 30 above the gate electrode 6a of the driving transistor 6b.

After performing dry etching method or wet etching method on the photothermal conversion layer 30 on which the resist 40a is formed, the resist 40a is peeled off and a semiconductor processing film 30a including the photothermal conversion material is formed on the semiconductor layer 9b as shown in FIG. 23 (processing film forming step). The semiconductor processing film 30a is a size according to the range where the microcrystalline silicon area is formed in the semiconductor layer 5b, and both edges are positioned above the gate electrode 5a. The semiconductor processing film for the driving transistor 6 is similarly formed on the semiconductor layer 9b with a size so that one edge is positioned above the gate electrode 6a according to the range where the microcrystalline silicon area is formed in the semiconductor layer 6b.

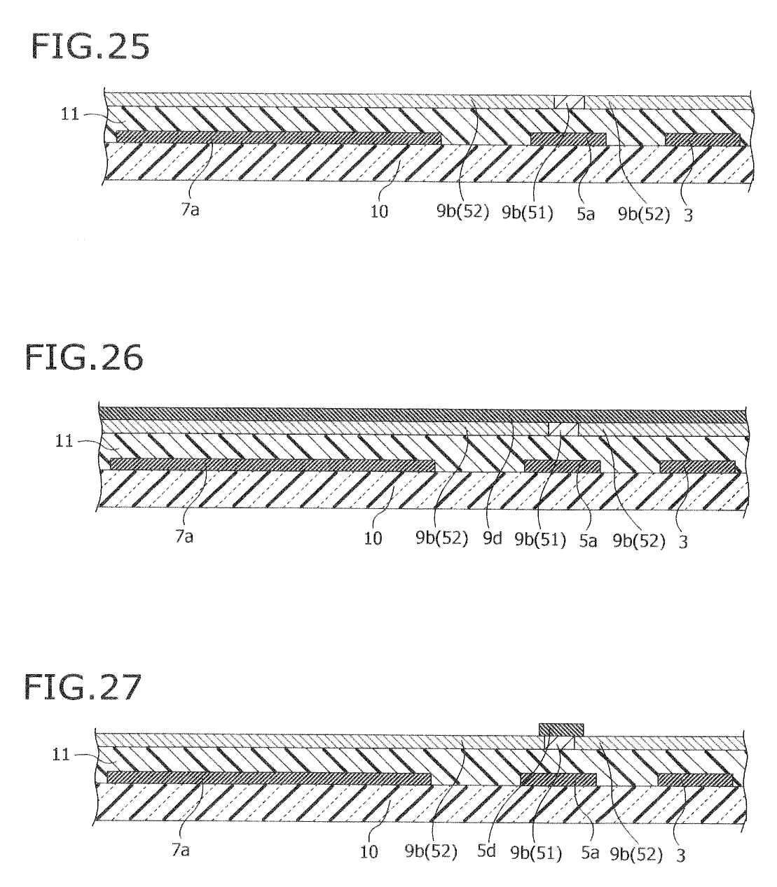

Next, as shown in FIG. 24, a laser beam (visible light or infrared light) is irradiated as predetermined processing on the semiconductor layer 9b on which the semiconductor processing film 30a is formed and the amorphous silicon of the semiconductor layer 9b portion covered by the semiconductor processing film 30a is crystallized to microcrystalline silicon to provide a microcrystalline silicon area 51 and an amorphous silicon area 52 in the semiconductor layer 9b (silicon crystallizing step). After forming the microcrystalline silicon area 51, as shown in FIG. 25, the semiconductor processing film 30a is removed by etching method, etc.

The semiconductor processing film on the driving transistor 6 is used to similarly form the microcrystalline silicon area 51 and the amorphous silicon area 52 in the semiconductor layer 9b.

Next, as shown in FIG. 26, a protecting insulating film 9d such as silicon nitride which is to be a channel protecting layer is formed by CVD method on the semiconductor layer 9b.

Then, as shown in FIG. 27, the protecting insulating film 9d is patterned by photolithography method, etching method, etc., and the channel protecting layer 5d is formed (protecting film forming step). The channel protecting layer 5d includes both edges which are to the amorphous silicon area 52 side than both edge faces of the microcrystalline silicon area 51 in the semiconductor layer 9b positioned above the gate electrode 5a and covers the microcrystalline silicon area 51 corresponding to the upper side of the gate electrode 5a.

The channel protecting layer 6d of the driving transistor 6 is formed similarly, and the channel protecting layer 6d includes one edge which is to the amorphous silicon area 62 side than one edge face of the microcrystalline silicon area 61 in the semiconductor layer 9b positioned above the gate electrode 6a and covers the microcrystalline silicon area 61 portion corresponding to the upper side of the gate electrode 6a.

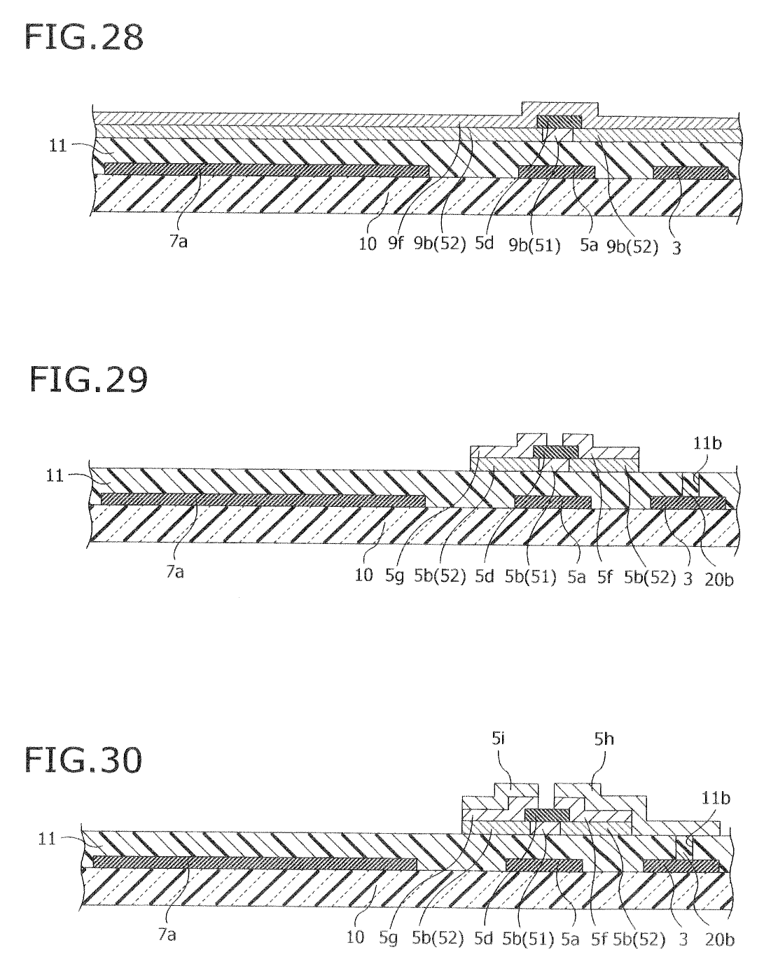

Next, as shown in FIG. 28, an extrinsic semiconductor layer 9f which is to be the extrinsic semiconductor layer is formed by CVD method on the semiconductor layer 9b on which the channel protecting layer 5d is formed.

Next, as shown in FIG. 29, the extrinsic semiconductor layer 9f and the semiconductor layer 9b are successively patterned by photolithography method to form the extrinsic semiconductor layers 5f and 5g and the semiconductor layer 5b (semiconductor layer forming step). The extrinsic semiconductor layers 6f and 6g and the semiconductor layer 6b of the driving transistor 6 are similarly formed.

Also, the contact holes 11a to 11c are formed by photolithography method and the contact plugs 20a to 20c are formed in the contact holes 11a to 11c.

Next, as shown in FIG. 30, the metal film to cover the extrinsic semiconductor layers 5f and 5g, the channel protecting layer 5d, the semiconductor layer 5b and the gate insulating film 11 is formed by sputtering method on the substrate 10, and the metal film is patterned by photolithography method to form a source electrode 5i and a drain electrode 5h on a pair of extrinsic semiconductor layers 5f and 5g (source and drain forming step).

The switch transistor 5 is manufactured as described above. The source electrode 6i and the drain electrode 6h of the driving transistor 6 are similarly formed to manufacture the driving transistor 6.

Also, in addition to the source electrode and the drain electrode, the scanning line 2, the voltage supplying line 4, the electrode 7b of the capacitor 7 are formed (see FIG. 17, FIG. 18).

After the switch transistor 5 and the driving transistor 6 are formed, the ITO film is deposited and patterned to form the pixel electrode 8a (see FIG. 17).

Next, the second insulating film 12 is formed to cover the switch transistor 5 and the driving transistor 6 (see FIG. 17 and FIG. 18). Similar to the gate insulating film 11, the second insulating film 12 is formed from silicon nitride, etc., by plasma CVD. The second insulating film 12 is patterned by photolithography method to form the opening 12a which exposes the center section of the pixel electrode 8a (see FIG. 17).

Next, after depositing photosensitive resin such as polyimide, etc., the photosensitive resin is exposed to light to form a bank 19 in a grid like shape including an opening 19a to expose the pixel electrode 8a (see FIG. 17).

Next, a liquid where material which is to be the hole injecting layer 8b and the light emitting layer 8c is dissolved or dispersed in the solvent is applied to the opening 19a of the bank 19 and the liquid is dried to sequentially form the hole injecting layer 8b and the light emitting layer 8c which are to be the carrier transporting layers (see FIG. 17).

Next, the opposite electrode 8d is formed on the entire face of the bank 19 and the light emitting layer 8c to manufacture the light emitting element 8 (see FIG. 17, FIG. 18) and thus to manufacture the EL panel 1.

As described above, the switch transistor 5 includes the semiconductor layer 5b including the microcrystalline silicon area 51 with amorphous silicon areas 52 at both edge sides. The channel protecting layer 5d covers the microcrystalline silicon area 51 of the semiconductor layer 5b and covers a portion of the amorphous silicon area 52 on the microcrystalline silicon area 51 side at both edge sides of the channel protecting layer 5d.

The length of the channel protecting layer 5d along the direction of the pair of extrinsic semiconductor layers 5f and 5g facing each other is formed longer than the length of the microcrystalline silicon area 51 portion of the semiconductor layer 5b and shorter than the length of gate electrode 5a. The extrinsic semiconductor layers 5f and 5g which is to be the source/drain area is not in direct contact with the microcrystalline silicon area 51 and is in contact with the amorphous silicon area 52 of the semiconductor layer 5b. With this, the drain electrode 5h and the source electrode 5i are electrically connected to the semiconductor layer 5b through the extrinsic semiconductor layer 5f and 5g. Consequently, generation of electron-hole pair due to microcrystalline silicon is suppressed, and the leak current is not generated easily.

The driving transistor 6 includes the semiconductor layer 6b including the microcrystalline silicon area 61 and the amorphous silicon area 62. The microcrystalline silicon area 61 is provided from the channel protecting layer 6d to the bottom face of the extrinsic semiconductor layer 6g. The amorphous silicon area 62 is provided from the edge side of the channel protecting layer 6d to the bottom face of the extrinsic semiconductor layer 6f.

As for the driving transistor 6, the direction of the current between the source and the drain is fixed to a direction from the amorphous silicon area 62 to the microcrystalline silicon area 61, and the extrinsic semiconductor layer 6f which is the upstream side of the current is not in direct contact with the microcrystalline silicon area 61 and is in contact with the amorphous silicon area 62 of the semiconductor layer 6b. With this, the drain electrode 6h and the source electrode 6i are electrically connected to the semiconductor layer 6b through the extrinsic semiconductor layer 6f and 6g. Consequently, generation of electron-hole pair due to microcrystalline silicon is suppressed and the leak current is not generated easily.

In particular, with respect to the current direction, since the length of the microcrystalline silicon area 61 portion is longer than the length of the amorphous silicon area 62 portion, the current can easily flow in the transistor. Consequently, even if the transistor size is small, a large current can be passed through. Therefore, the light emitting luminance of the light emitting element 8 is enhanced and the display performance of the EL panel 1 becomes favorable.

As described above, according to the switch transistor 5 and the driving transistor 6 including a semiconductor layer (5b, 6b) including a microcrystalline silicon area (51, 61) and amorphous silicon area (52, 62), the on current is enhanced by the microcrystalline silicon area and the leak current is reduced. Therefore, it can be said that the transistors are favorable transistors realizing both high on current and low leak current.

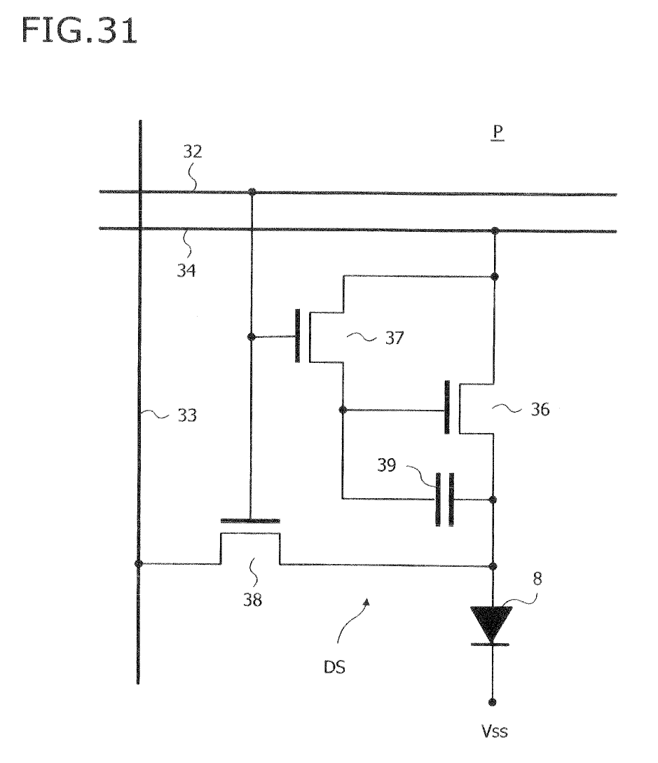

In the above described embodiments, other than the pixel P shown in FIG. 15, for example, a pixel P shown in FIG. 31 can also be used. The pixel P includes a pixel circuit DS and a light emitting element 8 controlled by the pixel circuit DS.

The pixel P is formed with a plurality of current supplying lines (anode lines) 34 connected to the plurality of pixel circuits DS arranged in a predetermined row, opposite electrode 8d (opposite electrode of light emitting element 8) to be a cathode of all pixels formed from a single electrode layer on which voltage Vss such as ground potential, etc. is applied, data line 33 connected to a plurality of pixel circuits DS each arranged in predetermined columns, and a plurality of gate lines 32 to select a first selective transistor 37 and second selective transistor 38 of the plurality of pixel circuits DS each arranged in predetermined columns. The current supplying line 34 is connected to a power source or current supplying driver which are not shown. The power source or current supplying driver modulates the applied voltage between the low level L and the high level H on each unit of a group of a plurality of current supplying lines 34 between during a scanning period T_{SC} and during a light emitting period T_{EM}. The current supplying line 34 is formed with the source electrode and drain electrode using the source/drain conductive layer which is to be the source electrode and the drain electrode of the transistor 36 to 38. The data line 33 is formed with the gate electrode using the gate conductive layer which is to be the gate electrode of each transistor 36 to 38 and the gate line 32 is formed using the source/drain conductive layer. The line provided in these separate layers and each electrode of the transistor are connected through a contact hole provided in the gate insulating film 11.

The gate electrode of the first selective transistor 37 and the gate electrode of the second selective transistor 38 are connected to the gate line 32 and the current supplying line 34 is connected to the drain electrode of the first selective transistor 37. Also, the source electrode of the first selective transistor 37 is connected to one electrode of the capacitor 39 provided in the gate insulating film 11.

Also, the drain electrode of the second selective transistor 38 is connected to the source electrode of the light emitting driving transistor 36, and the source electrode of the second selective transistor 38 is connected to the data line 33 through the contact hole provided in the gate insulating film 11. The drain electrode of the light emitting driving transistor 36 is connected to the current supplying line 34 and the gate electrode of the light emitting driving transistor 36 is connected to one electrode of the capacitor 39 through the contact hole. Also, the source electrode of the light emitting driving transistor 36 is connected to the other electrode of the capacitor 39 and the pixel electrode 8a (pixel electrode of the light emitting element 8). The capacitor 39 includes one electrode, the other electrode and a gate insulating film 11 which is to be a derivative between the electrodes.

The embodiments of the present invention are not limited to the above described embodiments and can be suitably modified without leaving the scope of the invention.

The entire disclosure of Japanese Patent Application No. 2009-153016 filed on Jun. 26, 2009 and Japanese Patent Application No. 2009-155216 filed on Jun. 30, 2009 including specification, claims, drawings and abstract are incorporated herein by reference in its entirety.

Although various exemplary embodiments have been shown and described, the invention is not limited to the embodiments shown. Therefore, the scope of the invention is intended to be limited solely by the scope of the claims that follow.

According to an aspect of the preferred embodiments of the present invention, there is provided a method of manufacturing a semiconductor device including:

forming a photothermal conversion layer in a second area where a semiconductor layer is formed other than a first area where line is formed; and

heating the semiconductor layer with the photothermal conversion layer by irradiating light on the first area and the second area.

Preferably, in the method of manufacturing a semiconductor device, an amorphous section of the semiconductor layer thermally crystallizes because of the heat caused by the irradiating light.

Preferably, the method of manufacturing a semiconductor device further includes removing the photothermal conversion layer after irradiating the light on the first area and the second area.

Preferably, the method of manufacturing a semiconductor device further includes forming a channel protecting layer wider than the photothermal conversion layer on the heated semiconductor layer after the photothermal conversion layer is removed.

Preferably, the method of manufacturing a semiconductor device further includes forming a first transistor in which the crystallized semiconductor layer is to be a channel layer, the crystallized semiconductor layer formed by irradiating the light to perform heating.

Preferably, in the method of manufacturing a semiconductor device, the step of forming the first transistor is comprises forming an electrode of the first transistor and a line of the first area by patterning a thin film including conductive material.

Preferably, the method of manufacturing a semiconductor device further includes forming a buffer layer between the semiconductor layer of the second area and the photothermal conversion layer.

Preferably, in the method of manufacturing a semiconductor device, the step of heating the semiconductor layer comprises transferring heat from the photothermal conversion layer to the semiconductor layer through the buffer layer;

removing the photothermal conversion layer; and

forming a channel protecting layer including the buffer layer by patterning.

Preferably, in the method of manufacturing a semiconductor device, the light irradiating step comprises irradiating the light on a third area in which the semiconductor layer is formed; and

forming a second transistor in which at least an amorphous part of the semiconductor layer of the third area is the channel layer.

According to an aspect of the preferred embodiments of the present invention, there is provided a semiconductor device manufactured by a method of manufacturing a semiconductor device including:

forming a photothermal conversion layer in a second area where a semiconductor layer is formed other than a first area where line is formed; and

heating the semiconductor layer with the photothermal conversion layer by irradiating light on the first area and the second area.

According to an aspect of the preferred embodiments of the present invention, there is provided a method of manufacturing a display device including a plurality of display pixels including a display element and a pixel driving circuit to drive the display element, the method including:

forming a photothermal conversion layer in a second area in which the semiconductor layer is formed other than a first area in which line is formed;

heating the semiconductor layer with the photothermal conversion layer by irradiating light on the first area and the second area; and

forming a first transistor of the pixel driving circuit in which the crystallized semiconductor layer is to be a channel layer, the crystallized semiconductor layer formed by irradiating the light to perform heating.

Preferably, in the method of manufacturing a display device, the first transistor is a transistor to supply a light emitting driving current to the display element.

Preferably, in the method of manufacturing a display device, the light irradiating step comprises irradiating the light on a third area in which the semiconductor layer is formed; and

forming a second transistor of the pixel driving circuit in which at least an amorphous part of the semiconductor layer of the third area is the channel layer.

Preferably, in the method of manufacturing a display device,

the first transistor is a transistor to supply light emitting driving current to the display element; and

the second transistor is a transistor to select the first transistor.

Preferably, in the method of manufacturing a display device,

the pixel driving circuit is connected to a selective line and a data line; and

the line functions as at least one of the selective line and the data line.

Preferably, in the method of manufacturing a display device, the semiconductor layer includes a crystallized semiconductor area and an amorphous semiconductor area positioned on each of both edges of the crystallized semiconductor area.

Preferably, the method of manufacturing a display device further includes forming a channel protecting layer wider than the photothermal conversion layer on the semiconductor layer.

Preferably, in the method of manufacturing a display device, the semiconductor layer includes a crystallized semiconductor area and an amorphous semiconductor area positioned on one edge of the crystallized semiconductor area.

According to an aspect of the preferred embodiments of the present invention, there is provided a method of manufacturing a display device including a pixel array in which a plurality of display pixels are arranged, a selective driver section to set the display pixel to a selective state, and a data driver section to supply display data to the display pixel, the method including:

forming a photothermal conversion layer above a semiconductor layer of a second area which is to be the data driver section other than above the semiconductor layer of a first area which is to be the pixel array; and

heating the semiconductor layer of the data driver section with the photothermal conversion layer by irradiating light on the first area and the second area.

Preferably, in the method of manufacturing a display device, the selective driver section is provided in the second area and the semiconductor layer of the selective driver section is also heated.

According to an aspect of the preferred embodiments of the present invention, there is provided a display device including:

a plurality of display pixels including:

a display element; and

a pixel driving circuit to drive the display element, wherein

the pixel driving circuit includes a transistor including:

a semiconductor layer including a crystallized semiconductor area and an amorphous semiconductor area positioned on each of both edges of the crystallized semiconductor area; and

a channel protecting layer wider than the crystallized area positioned on the semiconductor layer.

According to an aspect of the preferred embodiments of the present invention, there is provided a display device including:

a plurality of display pixels including:

a display element; and

a pixel driving circuit to drive the display element, wherein

the pixel driving circuit includes a transistor including:

a semiconductor layer including a crystallized semiconductor area and an amorphous semiconductor area positioned on one edge of the crystallized semiconductor area; and

a channel protecting layer positioned on the semiconductor layer and overlapped with a portion of the crystallized semiconductor area and a portion of the amorphous semiconductor area.

Preferably, in the display device, one of a source and a drain electrode of the transistor is connected to a pixel electrode of the display element, the one of the source and the drain electrode is connected to the crystallized semiconductor area side of the semiconductor layer and the other of the source or the drain electrode is connected to the amorphous semiconductor area side of the semiconductor layer.

What is claimed is:

1. A method of manufacturing a semiconductor device comprising:
forming a photothermal conversion layer in a second area where a semiconductor layer is formed other than a first area where line is formed; and
heating the semiconductor layer with the photothermal conversion layer by irradiating light on the first area and the second area.

2. The method of manufacturing a semiconductor device according to claim 1, wherein an amorphous section of the semiconductor layer thermally crystallizes because of the heat caused by the irradiating light.

3. The method of manufacturing a semiconductor device according to claim 1, further comprising removing the photothermal conversion layer after irradiating the light on the first area and the second area.

4. The method of manufacturing a semiconductor device according to claim 1, further comprising forming a channel protecting layer wider than the photothermal conversion layer on the heated semiconductor layer after the photothermal conversion layer is removed.

5. The method of manufacturing a semiconductor device according to claim 1, further comprising forming a first transistor in which the crystallized semiconductor layer is to be a channel layer, the crystallized semiconductor layer formed by irradiating the light to perform heating.

6. The method of manufacturing a semiconductor device according to claim 5, wherein the step of forming the first transistor is comprises forming an electrode of the first transistor and a line of the first area by patterning a thin film including conductive material.

7. The method of manufacturing a semiconductor device according to claim 1, further comprising forming a buffer layer between the semiconductor layer of the second area and the photothermal conversion layer.

8. The method of manufacturing a semiconductor device according to claim 7, wherein the step of heating the semiconductor layer comprises transferring heat from the photothermal conversion layer to the semiconductor layer through the buffer layer;
removing the photothermal conversion layer; and
forming a channel protecting layer including the buffer layer by patterning.

9. The method of manufacturing a semiconductor device according to claim 1, wherein the light irradiating step comprises irradiating the light on a third area in which the semiconductor layer is formed; and
forming a second transistor in which at least an amorphous part of the semiconductor layer of the third area is the channel layer.

10. A semiconductor device manufactured by the method of manufacturing a semiconductor device according to claim 1.

11. A method of manufacturing a display device including a plurality of display pixels including a display element and a pixel driving circuit to drive the display element, the method comprising:
forming a photothermal conversion layer in a second area in which the semiconductor layer is formed other than a first area in which line is formed;
heating the semiconductor layer with the photothermal conversion layer by irradiating light on the first area and the second area; and
forming a first transistor of the pixel driving circuit in which the crystallized semiconductor layer is to be a channel layer, the crystallized semiconductor layer formed by irradiating the light to perform heating.

12. The method of manufacturing a display device according to claim 11, wherein the first transistor is a transistor to supply a light emitting driving current to the display element.

13. The method of manufacturing a display device according to claim 11, wherein the light irradiating step comprises irradiating the light on a third area in which the semiconductor layer is formed; and
forming a second transistor of the pixel driving circuit in which at least an amorphous part of the semiconductor layer of the third area is the channel layer.

14. The method of manufacturing a display device according to claim 13, wherein
the first transistor is a transistor to supply light emitting driving current to the display element; and
the second transistor is a transistor to select the first transistor.

15. The method of manufacturing a display device according to claim 11, wherein
the pixel driving circuit is connected to a selective line and a data line; and
the line functions as at least one of the selective line and the data line.

16. The method of manufacturing a display device according to claim 11, wherein the semiconductor layer includes a crystallized semiconductor area and an amorphous semiconductor area positioned on each of both edges of the crystallized semiconductor area.

17. The method of manufacturing a display device according to claim 11, further comprising forming a channel protecting layer wider than the photothermal conversion layer on the semiconductor layer.

18. The method of manufacturing a display device according to claim 11, wherein the semiconductor layer includes a crystallized semiconductor area and an amorphous semiconductor area positioned on one edge of the crystallized semiconductor area.

19. A method of manufacturing a display device including a pixel array in which a plurality of display pixels are arranged, a selective driver section to set the display pixel to a selective state, and a data driver section to supply display data to the display pixel, the method comprising:
forming a photothermal conversion layer above a semiconductor layer of a second area which is to be the data driver section other than above the semiconductor layer of a first area which is to be the pixel array; and
heating the semiconductor layer of the data driver section with the photothermal conversion layer by irradiating light on the first area and the second area.

20. The method of manufacturing a display device according to claim 19, wherein the selective driver section is provided in the second area and the semiconductor layer of the selective driver section is also heated.

21. A display device comprising:
a plurality of display pixels including:
a display element; and
a pixel driving circuit to drive the display element, wherein
the pixel driving circuit includes a transistor including:
a semiconductor layer including a crystallized semiconductor area and an amorphous semiconductor area positioned on each of both edges of the crystallized semiconductor area; and
a channel protecting layer wider than the crystallized area positioned on the semiconductor layer.

22. A display device comprising:
a plurality of display pixels including:
a display element; and
a pixel driving circuit to drive the display element, wherein
the pixel driving circuit includes a transistor including:
a semiconductor layer including a crystallized semiconductor area and an amorphous semiconductor area positioned on one edge of the crystallized semiconductor area; and
a channel protecting layer positioned on the semiconductor layer and overlapped with a portion of the crystallized semiconductor area and a portion of the amorphous semiconductor area.

23. The display device according to claim 22, wherein one of a source and a drain electrode of the transistor is connected to a pixel electrode of the display element, the one of the source and the drain electrode is connected to the crystallized semiconductor area side of the semiconductor layer and the other of the source or the drain electrode is connected to the amorphous semiconductor area side of the semiconductor layer.
